(19) United States
(12) Patent Application Publication
(10) Pub. No.: US 2021/0068249 A1
(43) Pub. Date: Mar. 4, 2021

(54) ORGANIC/INORGANIC LAMINATES FOR HIGH FREQUENCY PRINTED CIRCUIT BOARD APPLICATIONS

(71) Applicant: Corning Incorporated, Corning, NY (US)

(72) Inventors: William Peter Addiego, Big Flats, NY (US); Heather Debra Boek, Corning, NY (US); Jennifer Anella Heine, Hammondsport, NY (US); Kenneth Edward Hrdina, Horseheads, NY (US); Dayue Jiang, Painted Post, NY (US); Geraint Owen, Palo Alto, CA (US); Paul George Rickerl, Endicott, NY (US); Tora Ann-Beatrice Eline SIrkka, Palo Alto, CA (US); WIlliam Richard Trutna, Atherton, CA (US)

(21) Appl. No.: 17/004,502

(22) Filed: Aug. 27, 2020

Related U.S. Application Data
(60) Provisional application No. 62/892,257, filed on Aug. 27, 2019.

(51) Int. Cl. H05K 1/03; H05K 1/02; H05K 3/00

(52) U.S. Cl. CPC H05K 1/036; H05K 1/0306; H05K 3/0064; H05K 1/0393; H05K 1/024

(57) ABSTRACT

A PCB laminate material includes at least one polymer layer and at least one inorganic layer, such that the PCB laminate material has a dielectric loss tangent of less than 6×10⁻³ at 10 GHz (or higher frequency). The inorganic layer or layers of the PCB laminate material may comprise silica-based materials (including silica fabrics), low-loss glass with a dielectric loss tangent of about 0.006 at 10 GHz (or higher frequency), glass-ceramics, or ceramic materials (e.g., alumina). PCB laminate materials may also include at least one fluoropolymer layer. PCB laminate materials described herein combine good dielectric performance (i.e., low dielectric loss), dimensional stability at elevated temperature (e.g., at 260° C. for 30 seconds), and sufficient mechanical strength to permit handling during production. Printed circuit boards comprising the PCB laminate materials and methods for making the same are also disclosed herein.

This application claims the benefit of priority under 35 U.S.C. § 119 of U.S. Provisional Application Ser. No. 62/892,257, filed on Aug. 27, 2019, the content of which is relied upon and incorporated herein by reference in its entirety.

### FIELD

The disclosure relates generally to the field of composites for printed circuit board (PCB) applications.

### BACKGROUND

A printed circuit board (“PCB”) typically consists of an insulating layer between two films of copper cladding. Ideally, the insulating layer should possess the following properties: good dielectric performance (i.e., low dielectric loss); dimensional stability at elevated temperature (e.g., at 260° C. for 30 seconds); sufficient mechanical strength and toughness to permit handling during production (e.g., via drilling) without damage, burr, or fracture; good adhesion; and fire resistance.

Currently, epoxy/glass composite materials (e.g., FR4) are used for the insulating layer, due to their excellent mechanical and thermal properties. Their dielectric losses, though relatively high, are adequate for present applications. However, their dielectric loss performance is inadequate for the GHz performance regime. In the near term, dielectric loss tangents of significantly less than 0.001 will be required for applications at several GHz. And over the long term (e.g., for 5G applications), loss tangents on the order of 0.0001 will be required. Although some commercially available materials have the required dielectric performance characteristics, none combine the required dielectric performance with the dimensional stability and mechanical strength and toughness necessary to withstand handling during PCB production.

Therefore, there exists a need for composite materials that have the mechanical, thermal, and dielectric performance characteristics required for PCB applications at several GHz.

### SUMMARY

In some embodiments, a printed circuit board (PCB) laminate material, comprises: (a) a first layer selected from a polymer layer, an inorganic layer, and an infiltrated inorganic layer; and (b) a second layer selected from a polymer layer, an inorganic layer, and an infiltrated inorganic layer, wherein the first layer is laminated to the second layer and the loss tangent of the PCB laminate material is no greater than 0.005 at 10 GHz or higher frequency.

In one aspect, which is combinable with any of the other aspects or embodiments, the PCB laminate material has a dielectric constant of less than or equal to 10.

In one aspect, which is combinable with any of the other aspects or embodiments, the PCB laminate material has a flexural modulus of about 1 GPa to about 400 GPa or a flexural strength of about 20 MPa to about 400 MPa.

In one aspect, which is combinable with any of the other aspects or embodiments, the first layer and/or the second layer of the PCB laminate material is an inorganic layer having a thickness between 20 μm and 700 μm. In one aspect, which is combinable with any of the other aspects or embodiments, the PCB laminate material comprises an inorganic layer comprising a glass having at least one of (i) a thickness less than or equal to 200 μm and (ii) a dielectric loss tangent of less than or equal to about 0.006 at 10 GHz (or higher frequency).

In one aspect, which is combinable with any of the other aspects or embodiments, the first layer and/or the second layer of the PCB laminate material comprises a polymer layer. In one aspect, which is combinable with any of the other aspects or embodiments, the polymer layer comprises at least one polymer selected from cyclic olefin copolymers, polystyrene polymers, fluoropolymers, polyetheretherketone polymers, polyetherimide polymers, liquid crystal polymers, polypropylene polymers, cyclic olefins, linear olefins, bi-cyclic olefin norbornene and ethylene, or combinations thereof. In one aspect, which is combinable with any of the other aspects or embodiments, the polymer layer comprises a polymer composite material, the polymer composite material comprising a cyclic olefin copolymer and a fluoropolymer, wherein the cyclic olefin copolymer and the fluoropolymer are present in a ratio of between 1:99 and 99:1. In one aspect, which is combinable with any of the other aspects or embodiments, the polymer layer comprises polytetrafluoroetheylene (PTFE, e.g., Teflon®), fluorinated ethylene propylene (FEP), poly(vinylidene) fluoride (PVDF), ethylene chlorotrifluoroethylene (ECTFE), perfluoroalkoxy (PFA), or combinations thereof.

In one aspect, which is combinable with any of the other aspects or embodiments, the PCB laminate material further comprises a third layer selected from a polymer layer, an inorganic layer, and an infiltrated inorganic layer, wherein the third layer is laminated to the first layer or the second layer.

In one aspect, which is combinable with any of the other aspects or embodiments, the PCB laminate material further comprises an adhesion promoter disposed between the first layer and the second layer.

In some embodiments, a printed circuit board (PCB) comprises (a) a PCB laminate material having a first side and a second side, the PCB laminate material comprising: (i) a first layer selected from a polymer layer, an inorganic layer, and an infiltrated inorganic layer; and (ii) a second layer selected from a polymer layer, an inorganic layer, and an infiltrated organic layer, wherein the first layer is laminated to the second layer; and (b) at least one conductive layer laminated onto the first side of the PCB laminate material, wherein the PCB laminate material has a dielectric loss tangent of no greater than 0.005 at 10 GHz (or higher frequency).

In one aspect, which is combinable with any of the other aspects or embodiments, the printed circuit board comprises a PCB laminate material having a dielectric constant of less than or equal to 10.

In one aspect, which is combinable with any of the other aspects or embodiments, the printed circuit board comprises a PCB laminate material having a flexural modulus of about 1 GPa to about 400 GPa or a flexural strength of about 20 MPa to about 400 MPa.

In one aspect, which is combinable with any of the other aspects or embodiments, the printed circuit board further comprises a second conductive layer laminated onto the second side of the PCB laminate material.

In one aspect, which is combinable with any of the other aspects or embodiments, the printed circuit board comprises a PCB laminate material, wherein the first layer and/or the second layer of the PCB laminate material is an inorganic layer having a thickness of 20 μm to 700 μm. In one aspect, which is combinable with any of the other aspects or embodiments, the inorganic layer comprises a glass layer having at least one of (i) a thickness less than or equal to 200 μm and (ii) a dielectric loss tangent of less than or equal to about 0.006 at 10 GHz (or higher frequency).

In one aspect, which is combinable with any of the other aspects or embodiments The printed circuit board comprises a PCB laminate material, wherein the first layer and/or the second layer comprises a polymer layer. In one aspect, which is combinable with any of the other aspects or embodiments, the polymer layer comprises at least one polymer selected from cyclic olefin copolymers, polystyrene polymers, fluoropolymers, polyetheretherketone polymers, polyetherimide polymers, liquid crystal polymers, polypropylene polymers, cyclic olefins, linear olefins, bi-cyclic olefin norbornene and ethylene, or combinations thereof. In one aspect, which is combinable with any of the other aspects or embodiments, the polymer layer comprises a polymer composite material, comprising a cyclic olefin copolymer and a fluoropolymer, wherein the cyclic olefin copolymer and the fluoropolymer are present in a ratio between 1:99 and 99:1. In one aspect, which is combinable with any of the other aspects or embodiments, the polymer layer comprises polytetrafluoroetheylene (PTFE, e.g., Teflon®), fluorinated ethylene propylene (FEP), poly(vinylidene) fluoride (PVDF), ethylene chlorotrifluoroethylene (ECTFE), perfluoroalkoxy (PFA), or combinations thereof.

In one aspect, which is combinable with any of the other aspects or embodiments, the printed circuit board further comprises an adhesion promoter disposed between the first layer and the second layer.

In one aspect, which is combinable with any of the other aspects or embodiments, the PCB laminate material of the printed circuit board further comprises a third layer selected from a polymer layer, an inorganic layer, and an infiltrated inorganic layer, wherein the third layer is laminated to the first layer or the second layer.

In some embodiments, a method of making a printed circuit board comprises: (a) preparing a PCB laminate material, comprising (i) contacting a first layer selected from a polymer layer, an inorganic layer, and an infiltrated inorganic layer with a second layer selected from a polymer layer, an inorganic layer, and an infiltrated inorganic layer; and (ii) laminating the first layer to the second layer to produce a PCB laminate material having a dielectric loss tangent of no greater than 0.005 at 10 GHz (or higher frequency); and (b) laminating the PCB laminate material to at least one conductive cladding layer, wherein step (ii) comprises heating the first layer and second layer.

In one aspect, which is combinable with any of the other aspects or embodiments, the PCB laminate material has a dielectric constant of less than or equal to 10.

In one aspect, which is combinable with any of the other aspects or embodiments, the PCB laminate material has a flexural modulus of about 1 GPa to about 400 GPa or a flexural strength of about 20 MPa to about 400 MPa.

In one aspect, which is combinable with any of the other aspects or embodiments, the first layer and/or the second layer of the PCB laminate material is an inorganic layer having a thickness between 20 μm and 700 μm. In one aspect, which is combinable with any of the other aspects or embodiments, the inorganic layer comprises a glass having at least one of (i) a thickness less than or equal to 200 μm and (ii) a dielectric loss tangent of less than or equal to about 0.006 at 10 GHz (or higher frequency).

In one aspect, which is combinable with any of the other aspects or embodiments, the first layer and/or the second layer of the PCB laminate material comprises a polymer layer. In one aspect, which is combinable with any of the other aspects or embodiments, the polymer layer comprises at least one polymer selected from cyclic olefin copolymers, polystyrene polymers, fluoropolymers, polyetheretherketone polymers, polyetherimide polymers, liquid crystal polymers, polypropylene polymers, cyclic olefins, linear olefins, bi-cyclic olefin norbornene and ethylene, or combinations thereof. In one aspect, which is combinable with any of the other aspects or embodiments, the polymer layer comprises a polymer composite material, comprising a cyclic olefin copolymer and a fluoropolymer, wherein the cyclic olefin copolymer and the fluoropolymer are present in a ratio between 1:99 and 99:1. In one aspect, which is combinable with any of the other aspects or embodiments, the polymer layer comprises polytetrafluoroetheylene (PTFE, e.g., Teflon®), fluorinated ethylene propylene (FEP), poly(vinylidene) fluoride (PVDF), ethylene chlorotrifluoroethylene (ECTFE), perfluoroalkoxy (PFA), or combinations thereof.

In one aspect, which is combinable with any of the other aspects or embodiments The method of making a printed circuit board further comprises, between (i) and (ii), contacting the first layer or the second layer with a third layer selected from a polymer layer, an inorganic layer, and an infiltrated inorganic layer, wherein (ii) further comprises laminating the third layer to the first layer or the second layer.

In one aspect, which is combinable with any of the other aspects or embodiments, the method of making a printed circuit board further comprises, before (i), applying an adhesion promoter to the first layer and/or the second layer.

### BRIEF DESCRIPTION OF THE DRAWINGS

FIG. 1A-D shows schematic illustrations of several embodiments of PCB laminate materials that may be prepared according to the present disclosure.

FIG. 2 is schematic illustration of one embodiment of a three-layer PCB laminate material according to the present disclosure.

FIG. 3 shows a cross-sectional scanning electron microscope (SEM) image of a three-layer PCB laminate structure including a silica layer between two Topas® polymer layers.

FIG. 4 shows a cross-sectional scanning electron microscope (SEM) image of a three-layer PCB laminate structure including a Topas® polymer layer between two alumina layers.

FIG. 5 shows a schematic illustration of different surface morphologies of fluoropolymer layers that may be included in PCB laminates.

FIG. 6 shows a schematic illustration of additional embodiments of three-layer PCB laminate materials according to the present disclosure.

FIG. 7 shows a schematic illustration of two different embodiments of seven-layer PCB laminates containing (i) Topas®-PTFE composite layers, (ii) fluoropolymer layers, and (iii) silica fabric layers.

FIG. 8 shows a schematic illustration for a melt process for producing composite polymer layers.

FIG. 9 shows a schematic illustration of another embodiment of a PCB laminate material according to the present disclosure, in which a low-loss glass sheet is laminated between two polymer layers.

FIGS. 10A-B show SEM images revealing the surface morphology of fused silica tape obtained from continuous sintering at 1250° C. and 3 in/min (FIG. 10A) and 1300° C. and 3 in/min (FIG. 10B).

FIGS. 11A-B show SEM images of porous silica sheets produced by a batch-sintering process from a silica sheet using IMSIL A25 with 10 vol-% 22 m²/g amorphous silica.

FIGS. 12A-B show SEM images of porous silica sheets prepared by an electrostatic spray process.

FIGS. 13A-B show SEM images and accompanying EDX data for a porous silica scaffold infiltrated with polystyrene (FIG. 13A) and a bare porous silica scaffold without polystyrene (FIG. 13B).

FIG. 14 shows a schematic illustration of the layup for laminating silica/Topas®/silica (“STS”) PCB laminates.

FIG. 15 is a schematic illustration of a three-layer, symmetrical laminate including layers of two different materials.

FIG. 16 is a cross-sectional schematic illustration of a nine-layer PCB laminate for which dielectric properties were calculated according to the present disclosure.

FIG. 17 shows a cross-sectional view of a single layer of a PCB laminate material.

FIGS. 18A-B show cross-sectional optical images of three-layer PCB laminates with a FEP layer (FIG. 18A) or a PFA layer (FIG. 18B) between two Topas®-PTFE layers.

FIGS. 19A-B show photographs demonstrating the mechanical properties of a seven-layer PCB laminate material according to the present disclosure.

FIGS. 20A-B show cross-sectional optical images of the seven-layer PCB laminates prepared according to the schematic illustration in FIG. 7.

FIG. 21 is a bar graph showing measured dielectric loss tangents for the three-layer and seven-layer PCB laminates prepared according to the schematic illustrations in FIGS. 6 and 7, respectively.

FIG. 22 is a schematic illustration of three-layer PCB laminate materials and silica and alumina sheets prepared for mechanical testing.

FIG. 23 is a schematic illustration of the test method for flexural strength and flexural modulus.

FIG. 24 shows load-deflection plots for five Topas®/silica/Topas® (“TST”) PCB laminates.

FIG. 25 shows the measured flexural modulus and flexural strength for TST (black dots on white background), STS (white dots on black background), TAT (downward sloping diagonal stripes) and ATA (upward sloping diagonal stripes). Average values are shown as white markers with black borders.

FIGS. 26A-B show 1-mm holes drilled through a Topas®/silica/Topas® (“TST”) laminate (FIG. 26A) and a Topas®/alumina/Topas® (“TAT”) laminate (FIG. 26B).

### DETAILED DESCRIPTION

The present inventors surprisingly discovered that by laminating thin polymer layers with good dielectric loss properties (e.g., dielectric loss tangents less than or equal to 0.001), to thin inorganic layers (20 μm to 700 μm) having excellent mechanical properties, the resulting PCB laminate materials exhibit greatly improved mechanical performance without sacrificing the excellent dielectric loss properties of the polymer layers. The resulting PCB laminate materials exhibit excellent dielectric performance (i.e., loss tangents of about 0.0005), dimensional stability at elevated temperature (e.g., at 260° C. for 30 seconds), and sufficient mechanical strength and toughness to permit handling during production (e.g., via drilling).

Extremely thin and bendable glass and other inorganic layers (<1 mm, and especially less than 0.25 mm) have not been widely available for study, and the concept of bendable or rollable glass is a relatively new concept. Thus, the relevant mechanical performance of these materials has not been fully explored. Without being bound to any particular theory, it is speculated that improvements in machinability of PCB laminate materials according to the present disclosure stems from the high flexibility of the inorganic layers, which may allow some deformation without breaking or build-up of only minimal energy before breaking occurs, thereby minimizing crack propagation. Additionally, the high expansion of the polymer compared to the glass or ceramic may put the ceramic or glass in compression, which may also minimize crack propagation. Because ceramics and glass are strong in compression and weak in tension, even a small compressive force may be highly beneficial. Furthermore, the low modulus of the polymer may uniformly distribute stresses as a result of the lower modulus polymer.

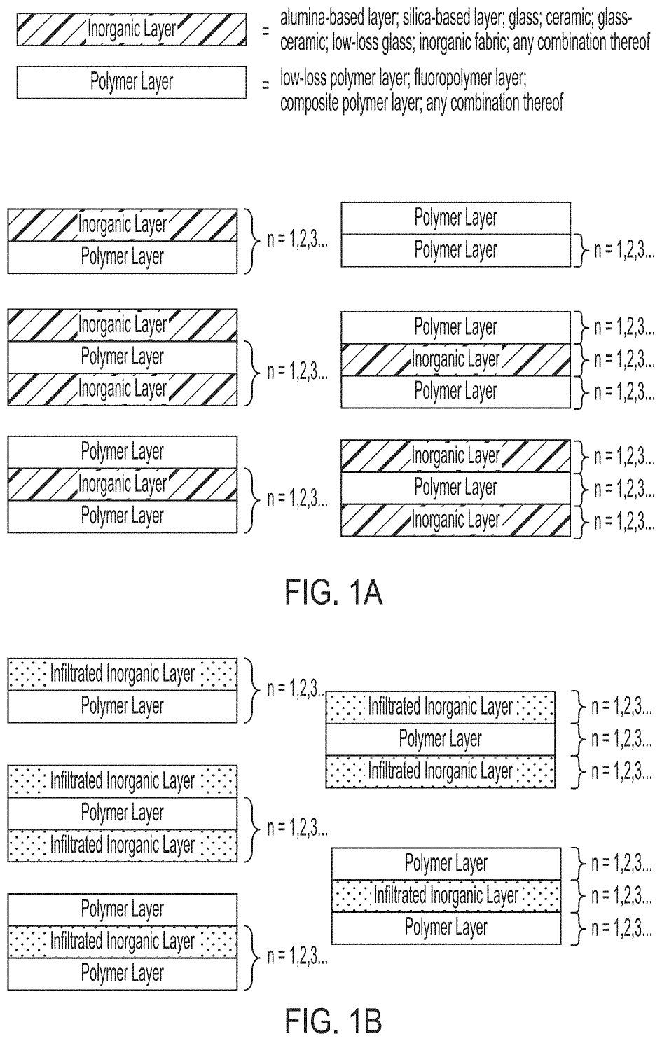

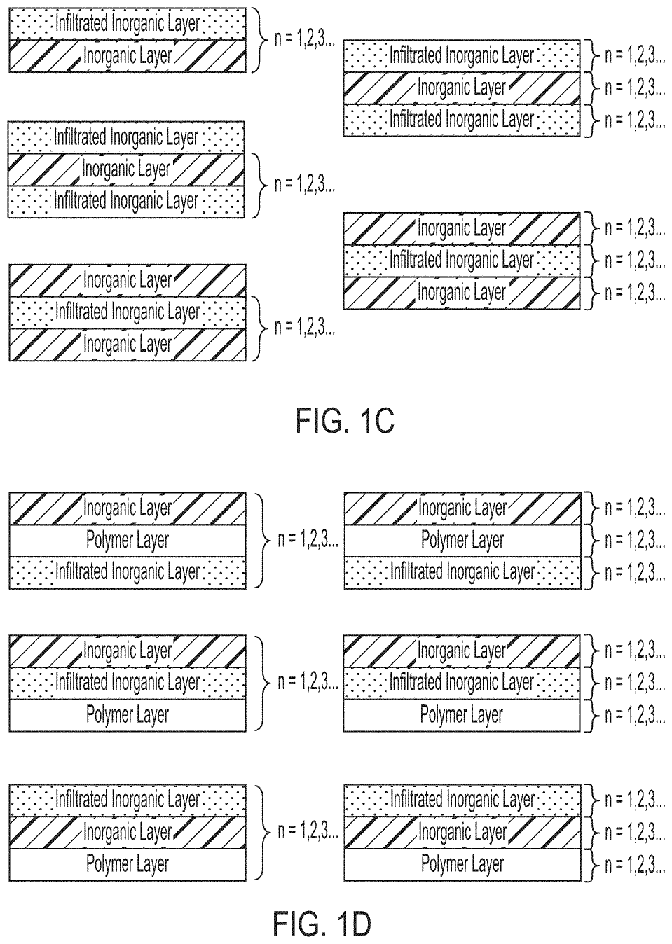

Referring now to FIGS. 1A-D, PCB laminate materials according to the present disclosure may comprise multiple layers of multiple different materials that possess, collectively or individually, dielectric and mechanical properties making them suitable in PCB applications at several GHz. Although the embodiments shown in FIG. 1 are non-limiting, the Figures show that a PCB laminate material comprises at least one polymer layer, which can be a low-loss polymer, fluoropolymer, or polymer composite. A PCB laminate material may further comprise at least one inorganic layer, which can be alumina-based, silica-based, a ceramic, a glass-ceramic, a glass (including a low-loss glass), or an inorganic fabric. A PCB laminate material may also comprise one or more “infiltrated” layers laminated to one or more polymer and/or inorganic layers.

As illustrated in FIGS. 1A-D, in any of the PCB laminates according to the present disclosure, the at least one polymer layer or the at least one inorganic layer can be laminated to one or more other layers to produce stacked PCB laminates comprising any combination of the materials described herein, arranged in any order. For example, a polymer layer may be laminated between two inorganic layers (FIG. 1A) to form a three-layer laminate. In this case, the two inorganic layers may comprise the same material (e.g., alumina), or the two inorganic layers may each comprise different materials (e.g., a boron-phosphate glass ceramic layer and a silica layer, etc.). In another embodiment (FIG. 1A), a PCB laminate material comprises an inorganic layer laminated to, and disposed between, two polymer layers, which may be identical to one another or each comprise a different material (e.g., a Topas® layer and a Topas®-PTFE composite layer, etc.). As shown by the Figures, the PCB laminates may comprise multiple layers (e.g., 2, 3, 4, 5, 6, 7, 8, 9, 10, or more) with any combination and order of polymer layers, inorganic layers, and/or infiltrated layers.

The PCB laminate compositions disclosed herein can comprise, consist essentially of, or consist of one or more of the following components.

### Polymer Layers

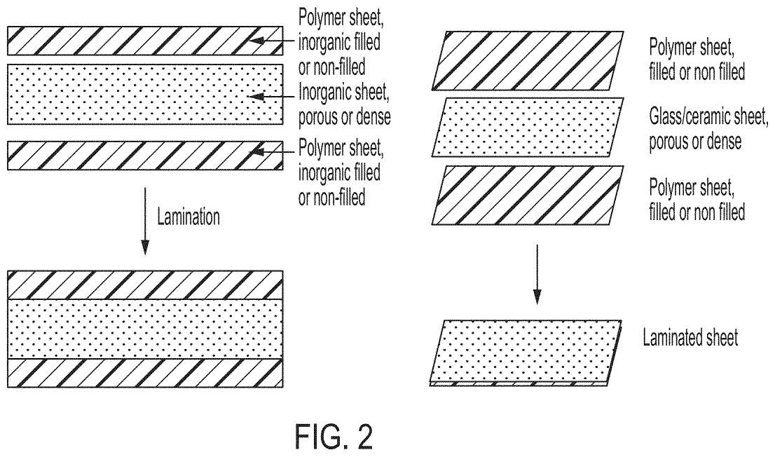

Referring to FIGS. 1 and 2, in some embodiments, PCB laminate materials according to the present disclosure comprise one or more polymer layers. In particular embodiments, the polymer layers may comprise low-loss polymers or copolymers (e.g., Topas®), fluoropolymers, or composite polymers (e.g., Topas® powder-PTFE composites). In some embodiments, PCB laminate materials according to the present disclosure include multiple polymer layers, wherein each polymer layer may comprise the same materials (e.g., composite polymers) as the other polymer layers, or wherein the polymer layers may individually comprise different materials.

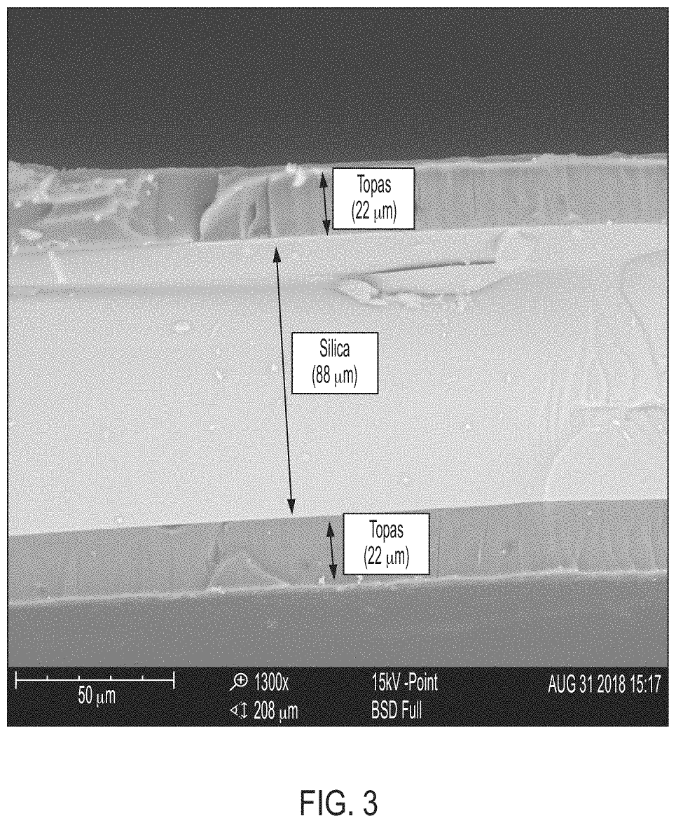

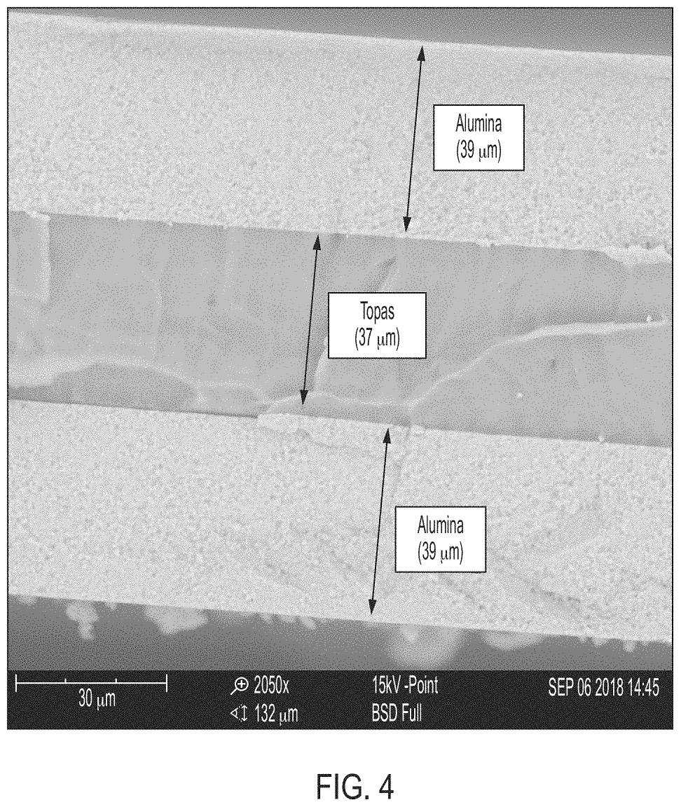

Referring now to FIGS. 3 and 4, in some embodiments, a polymer layer has a thickness of between 10 μm and 1 mm, between 15 μm and 800 μm, between 20 μm and 700 μm, between 30 μm and 650 μm, between 40 μm and 600 μm, between 50 μm and 550 μm, between 60 μm and 500 μm, between 70 μm and 450 μm, between 80 μm and 400 μm, between 90 μm and 350 μm, between 100 μm and 300 μm, or between 150 μm and 250 μm, or any range thereinbetween. In some embodiments, a polymer layer has a thickness of about 20 μm, about 30 μm, about 40 μm, about 50 μm, about 60 μm, about 70 μm, about 80 μm, about 90 μm, about 100 μm, about 110 μm, about 120 μm, about 130 μm, about 140 μm, about 150 μm, about 200 μm, about 250 μm, about 300 μm, about 350 μm, about 400 μm, about 450 μm, about 500 μm, about 550 μm, about 600 μm, about 650 μm, about 700 μm, about 800 μm, about 900 μm, or about 1 mm, or any intermediate value therein.

In any of the embodiments disclosed herein, a polymer layer may have a dielectric loss tangent at 10 GHz (or higher frequency) of less than 5×10⁻³, less than 4×10⁻³, less than 3×10⁻³, less than 2×10⁻³, less than 1×10⁻³, less than 9×10⁻⁴, less than 8×10⁻⁴, less than 7×10⁻⁴, less than 6×10⁻⁴, less than 5×10⁻⁴, less than 4×10⁻⁴, less than 3×10⁻⁴, less than 2×10⁻⁴, less than 1×10⁻⁴, less than 9×10⁻⁵, less than 8×10⁻⁵, less than 7×10⁻⁵, less than 6×10⁻⁵, less than 5×10⁻⁵, less than 4×10⁻⁵, less than 3×10⁻⁵, less than 2×10⁻⁵, or less than 1×10⁻⁵, or any range therein. In some embodiments, a low-loss polymer layer has a dielectric loss tangent at 10 GHz (or higher frequency) of about 5×10⁻³, about 4×10⁻³, about 3×10⁻³, about 2×10⁻³, about 1×10⁻³, about 9×10⁻⁴, about 8×10⁻⁴, about 7×10⁻⁴, about 6×10⁻⁴, about 5×10⁻⁴, about 4×10⁻⁴, about 3×10⁻⁴, about 2×10⁻⁴, about 1×10⁻⁴, about 9×10⁻⁵, about 8×10⁻⁵, about 7×10⁻⁵, about 6×10⁻⁵, about 5×10⁻⁵, about 4×10⁻⁵, about 3×10⁻⁵, about 2×10⁻⁵, or about 1×10⁻⁵, or any intermediate value thereinbetween.

By way of non-limiting example, in some embodiments, a polymer layer according to the present disclosure may comprise, consist essentially of, or consist of any of the following types of materials.

Low-Loss Polymers or Copolymers

In some embodiments, PCB laminate materials according to the present disclosure comprise one or more polymer layers comprising low-loss polymers or copolymers. In some embodiments, the polymer layer(s) comprise one or more polymers selected from (but not limited to) cyclic olefin polymers or copolymers (“COCs”) (e.g., the Topas® COC polymers, APEL®, Zeonor®, Zeonex®, ARTON®, etc.), polystyrene polymers (PS), polyetheretherketone polymers (PEEK), polyetherimide polymers (PEI), liquid crystal polymers, polypropylene polymers, cyclic olefins, linear olefins, bi-cyclic olefin norbornene, ethylene, polyisobutylene, 4-methylpentene, (dimethyl) polyphenyloxide (PPO), or combinations thereof.

In particular embodiments, a polymer layer may comprise low-loss polymers or co-polymers selected from the Topas® family, which include cyclic olefin polymers and copolymers comprising cyclic olefin, cyclopentene, and ethylene copolymers. The exact member of the Topas® family chosen depends on desired mechanical and thermal properties required for processing (e.g., during a lamination process) or in the final laminates. In particular embodiments, the low-loss polymers are cyclic olefin polymers or copolymers (e.g., Topas® 8700S, Topas® 6013S, or combinations thereof).

In some embodiments, a polymer layer has a storage modulus at 260° C. of greater than 1×10⁸ Pa, greater than 2×10⁸ Pa, greater than 3×10⁸ Pa, greater than 4×10⁸ Pa, greater than 5×10⁸ Pa, greater than 6×10⁸ Pa, greater than 7×10⁸ Pa, greater than 8×10⁸ Pa, greater than 9×10⁸ Pa, or greater than 1×10⁹ Pa, or any range thereinbetween. In some embodiments, a polymer layer has a storage modulus at 260° C. of about 1×10⁸ Pa, about 2×10⁸ Pa, about 3×10⁸ Pa, about 4×10⁸ Pa, about 5×10⁸ Pa, about 6×10⁸ Pa, about 7×10⁸ Pa, about 8×10⁸ Pa, about 9×10⁸ Pa, or about 1×10⁹ Pa, or any intermediate value therein.

Fluoropolymers

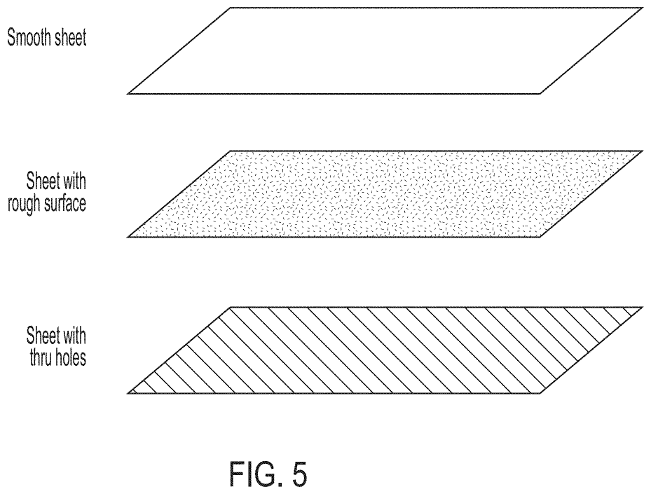

Referring to FIGS. 5-7, in some embodiments, the PCB laminate materials according to the present disclosure comprise one or more fluoropolymer layers. In some embodiments, the fluoropolymer is selected from the group comprising: polytetrafluoroetheylene (PTFE, e.g., Teflon®), fluorinated ethylene propylene (FEP), poly(vinylidene) fluoride (PVDF), ethylene chlorotrifluoroethylene (ECTFE), perfluoro alkoxy (PFA), or combinations thereof. In particular embodiments, the fluoropolymer layer comprises FEP or PFA.

In some embodiments, the fluoropolymer layer has a thickness of 10 μm to 1 mm, 20 μm to 900 μm, 30 μm to 800 μm, 40 μm to 700 μm, 50 μm to 600 μm, 60 μm to 500 μm, 70 μm to 400 μm, 80 μm to 300 μm, 90 μm to 200 μm, or 100 μm to 150 μm, or any range therein. In some embodiments, the fluoropolymer layer has a thickness of 75 μm to 125 μm. In some embodiments, the fluoropolymer layer has a thickness of 10 μm, 15 μm, 20 μm, 25 μm, 30 μm, 35 μm, 40 μm, 45 μm, 50 μm, 55 μm, 60 μm, 65 μm, 70 μm, 75 μm, 80 μm, 85 μm, 90 μm, 95 μm, 100 μm, 105 μm, 110 μm, 115 μm, 120 μm, 125 μm, 130 μm, 135 μm, 140 μm, 145 μm, 150 μm, 175 μm, 200 μm, 250 μm, 300 μm, 350 μm, 400 μm, 450 μm, or 500 μm, 550 μm, 600 μm, 650 μm, 700 μm, 750 μm, 800 μm, 850 μm, 900 μm, 950 μm, or 1 mm, or any value thereinbetween.

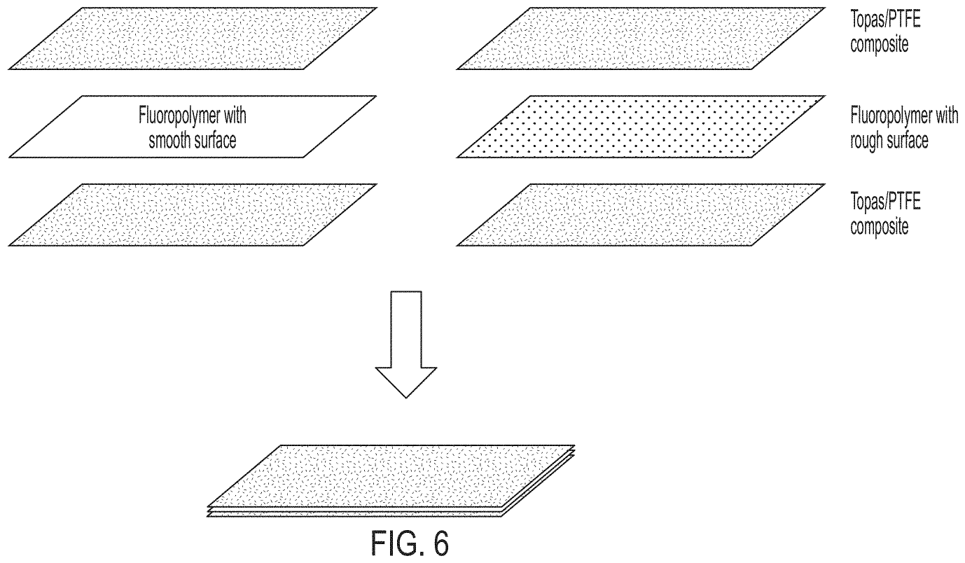

Referring to FIG. 5 and FIG. 6, the fluoropolymer layers of the present disclosure may have a range of different surface morphologies and configurations. For example, a fluoropolymer layer may be a smooth sheet, a rough sheet, or a fabric containing through-holes.

In some embodiments, a fluoropolymer layer a may be cleaned, roughened, or embossed to improve its wettability with adhesion promoters for effective lamination with glass or ceramic sheets, or to increase its surface area and real area of contact with other layers to which it may be laminated. In some embodiments, the fluoropolymer layers may be plasma treated to improve wettability with adhesion promoters.

Composite Polymer Materials

Referring now to FIGS. 6-8, in some embodiments, the PCB laminate materials according to the present disclosure comprise one or more polymer layers comprising composite polymer materials (or “polymer composite materials”). In some embodiments, a composite polymer material (or composite polymer layer) comprises: (i) at least one thermoplastic polymer; and (ii) at least one PTFE-based polymer, wherein the composite has a dielectric loss tangent of less than 1×10⁻³ at 10 GHz (or higher frequency). These materials and methods of preparing the same have been described in U.S. Provisional Patent Application No. 62/819,852, hereby incorporated by reference in its entirety.

In some embodiments, the at least one thermoplastic polymer comprises at least one of cyclic olefin copolymers (e.g., Topas®), polystyrene polymers, fluoropolymers, polyetheretherketone polymers, polyetherimide polymers, liquid crystal polymers, polypropylene polymers, cyclic olefins, linear olefins, bi-cyclic olefin norbornene and ethylene, or combinations thereof.

In some embodiments, the at least one thermoplastic polymer comprises at least one of:

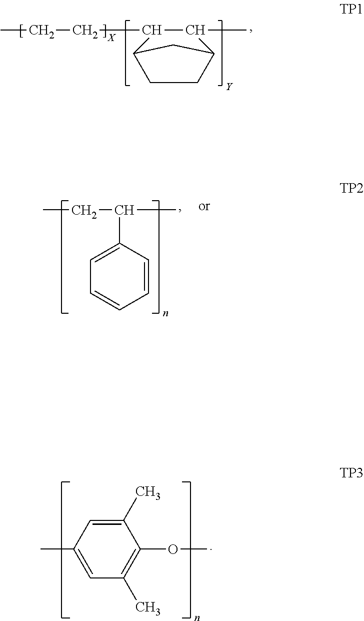

In some embodiments, the at least one thermoplastic polymer comprises a first thermoplastic polymer and a second thermoplastic polymer, wherein the first thermoplastic polymer comprises a fluoropolymer, and the second thermoplastic polymer comprises cyclic olefin copolymers, polystyrene polymers, polyetheretherketone polymers, polyetherimide polymers, liquid crystal polymers, polypropylene polymers, cyclic olefins, linear olefins, bi-cyclic olefin norbornene and ethylene, or combinations thereof.

In one aspect, which may be combined with any of the other aspects or embodiments, “PTFE-based polymers” may refer to homopolymers of tetrafluoroethylene (TFE) or copolymers of TFE with one or more monomers. Co-monomers having ethylene unsaturation which can be used are both of hydrogenated and fluorinated type; among the hydrogenated ones include ethylene, propylene, acrylic monomers (e.g., methyl methacrylate, (meth)acrylic acid, butylacrylate, hydroxyethylhexylacrylate, etc.), styrene monomers (e.g., styrene, etc.). Fluorinated co-monomers include C₃-C₈ perfluoroolefins (e.g., hexafluoropropene (HFP)); C₂-C₈ hydrogenated fluoroolefins (e.g., vinyl fluoride (VF), vinylidene fluoride (VDF), trifluoroethylene, hexafluoroisobutene, perfluoroalkylethylene CH₂=CH—R_{f}, wherein R_{f} is a C₁-C₆ perfluoroalkyl); C₂-C₈ chloro- and/or bromo- and/or iodo-fluoroolefins (e.g., chlorotrifluoroethylene (CTFE)); CF₂═CFOR_{f}(per)fluoroalkylvinylethers (PAVE), wherein R_{f} is a C₁-C₆ (per)fluoroalkyl (e.g., CF₃, C₂F₅, C₃F₇, etc.); CF₂═CFOX (per)fluoro-oxyalkylvinylethers, wherein X is a C₁-C₁₂ alkyl, or a C₁-C₁₂ oxyalkyl, or a C₁-C₁₂(per)fluoro-oxyalkyl having one or more ether groups (e.g., perfluoro-2-propoxy-propyl, fluorodioxoles, perfluorodioxoles, etc.). In some embodiments, the PTFE-based fluoropolymer is selected from the group comprising: fluorinated ethylene propylene (FEP), poly(vinylidene) fluoride (PVDF), ethylene chlorotrifluoroethylene (ECTFE), perfluoro alkoxy (PFA), or combinations thereof.

In some embodiments, the ratio of the at least one thermoplastic polymer to the at least one PTFE-based polymer is in a range of about 1:99 to about 99:1, about 1:90 to about 90:1, about 1:80 to about 80:1, about 1:70 to about 70:1, about 1:60 to about 60:1, about 1:50 to about 50:1, about 1:40 to about 40:1, about 1:30 to about 30:1, about 1:20 to about 20:1, about 1:10 to about 10:1, about 1:5 to about 5:1, about 1:3 to about 3:1, about 1:2 to about 2:1, about 1:1.5 to about 1.5:1, or about 1:1, or any range thereinbetween. In some embodiments, the ratio of the at least one thermoplastic polymer to the at least one PTFE-based polymer is about 1:99, about 5:95, about 10:90, about 15:85, about 20:80, about 25:75, about 30:70, about 35:65, about 40:60, about 45:55, about 50:50, about 55:45, about 60:40, about 65:35, about 70:30, about 75:25, about 80:20, about 85:15, about 90:10, about 95:5, or about 99:1, or any ratio therein. In some embodiments, the ratio of the at least one thermoplastic polymer to the at least one PTFE-based polymer is between 40:60 and 60:40.

In some embodiments, the composite polymer comprises at least one thermoplastic polymer present in a range of 1 wt. % to 99 wt. %, or 5 wt. % to 95 wt. %, or 10 wt. % to 90 wt. %, or 15 wt. % to 85 wt. %, or 20 wt. % to 80 wt. %, or 25 wt. % to 75 wt. %, or 30 wt. % to 70 wt. %, or 35 wt. % to 65 wt. %, or 40 wt. % to 60 wt. %, or 45 wt. % to 55 wt. %, or 1 wt. % to 30 wt. %, or 30 wt. % to 60 wt. %, or 60 wt. % to 99 wt. %, or 15 wt. % to 45 wt. %, or 45 wt. % to 60 wt. %, or 60 wt. % to 75 wt. %, or 75 wt. % to 90 wt. %, or 1 wt. % to 20 wt. %, or 1 wt. % to 10 wt. %, or 80 wt. % to 99 wt. %, or 90 wt. % to 99 wt. %, or any range or value therein. In some embodiments, the composite polymer comprises a thermoplastic polymer present at about 1 wt. %, about 5 wt. %, about 10 wt. %, about 15 wt. %, about 20 wt. %, about 25 wt. %, about 30 wt. %, about 35 wt. %, about 40 wt. %, about 45 wt. %, about 50 wt. %, about 55 wt. %, about 60 wt. %, about 65 wt. %, about 70 wt. %, about 75 wt. %, about 80 wt. %, about 85 wt. %, about 90 wt. %, about 95 wt. %, or about 99 wt. %, or any value thereinbetween, relative to the weight of the composite polymer.

In some embodiments, the composite polymer comprises at least one PTFE-based polymer present in a range of 1 wt. % to 99 wt. %, or 5 wt. % to 95 wt. %, or 10 wt. % to 90 wt. %, or 15 wt. % to 85 wt. %, or 20 wt. % to 80 wt. %, or 25 wt. % to 75 wt. %, or 30 wt. % to 70 wt. %, or 35 wt. % to 65 wt. %, or 40 wt. % to 60 wt. %, or 45 wt. % to 55 wt. %, or 1 wt. % to 30 wt. %, or 30 wt. % to 60 wt. %, or 60 wt. % to 99 wt. %, or 15 wt. % to 45 wt. %, or 45 wt. % to 60 wt. %, or 60 wt. % to 75 wt. %, or 75 wt. % to 90 wt. %, or 1 wt. % to 20 wt. %, or 1 wt. % to 10 wt. %, or 80 wt. % to 99 wt. %, or 90 wt. % to 99 wt. %, or any range or value therein. In some embodiments, the composite polymer comprises a PTFE-based polymer present at about 1 wt. %, about 5 wt. %, about 10 wt. %, about 15 wt. %, about 20 wt. %, about 25 wt. %, about 30 wt. %, about 35 wt. %, about 40 wt. %, about 45 wt. %, about 50 wt. %, about 55 wt. %, about 60 wt. %, about 65 wt. %, about 70 wt. %, about 75 wt. %, about 80 wt. %, about 85 wt. %, about 90 wt. %, about 95 wt. %, or about 99 wt. %, or any value thereinbetween, relative to the weight of the composite polymer.

In some embodiments, the thermoplastic polymer and/or the PTFE-based polymer of the composite polymer may be initially in the form of a pellet, particle, liquid, powder, fiber (short or long), tape, weave, filament, yarn, sheet, etc.

### Inorganic Layers

Referring to FIGS. 1-4, 7, and 9, in one aspect, which may be combined with any of the other aspects or embodiments, the PCB laminate materials according to the present disclosure comprise at least one inorganic layer, which may include a silica-based material, an alumina-based material, a ceramic, a glass-ceramic, a glass (including a low-loss glass), inorganic fabric (e.g. silica weave), or other suitable inorganic material. In some embodiments, the at least one inorganic layer comprises at least one of silica-based material (SiO₂), a low dielectric loss ceramic (e.g., alumina (Al₂O₃), alumina trihydrate (Al₂O₃.3H₂O), etc.), antimony oxide (Sb₂O₃, Sb₂O₅, Sb₂O₄), barium sulfate (BaSO₄), calcium carbonate (CaCO₃), kaolinite (Al₂Si₂O₅(OH)₄), magnesium hydroxide (Mg(OH)₂), talc (Mg₃Si₄O₁₀(OH)₂), titanium dioxide (TiO₂), or combinations thereof.

In another aspect, which may be combined with any of the other aspects or embodiments, the one or more inorganic layers may comprise one or more low loss glasses, which may include pure silica (100% silica) or doped silica. Examples of low loss dopants in doped silica include, but are not limited to, TiO₂, Al₂O₃, ZrO₂, GeO₂, B₂O₃, Nb₂O₅, Ta₂O₅, ZnO, MgO, CaO, SrO, BaO, P₂O₅, Sb₂O₃, SnO₂, As₂O₃, Li₂O, Na₂O, K₂O, F, or combinations thereof. As an example, TiO₂-doped silica glasses have improved fatigue resistance and lower thermal expansion than pure silica and therefore may be well-suited to particular applications. In a particular embodiment, the inorganic layer comprises pure (100%) silica.

In some embodiments, the inorganic layer has a thickness of between about 20 μm to about 1 mm, about 20 μm to about 900 μm, about 20 μm to about 800 μm, about 20 μm to about 700 μm, about 20 μm to about 600 μm, about 20 μm to about 500 μm, about 20 μm to about 400 μm, about 20 μm to about 300 μm, about 20 μm to about 200 μm, about 20 μm to about 150 μm, about 20 μm to about 130 μm, about 20 μm to about 120 μm, about 20 μm to about 110 μm, or about 20 μm to about 100 μm, or any range therein. In some embodiments, the inorganic layer has a thickness of about 10 μm, about 20 μm, about 30 μm, about 40 μm, about 50 μm, about 60 μm, about 70 μm, about 80 μm, about 90 μm, about 100 μm, about 110 μm, about 120 μm, about 130 μm, about 140 μm, about 150 μm, about 200 μm, about 250 μm, about 300 μm, about 350 μm, about 400 μm, about 450 μm, about 500 μm, about 550 μm, or about 600 μm, about 650 μm, about 700 μm, about 750 μm, about 800 μm, about 850 μm, about 900 μm, about 950 μm, about 1 mm, or any value thereinbetween. In particular embodiments, the inorganic layers have a thickness of less than or equal to 200 μm, or less than or equal to 100 μm.

In some embodiments, the inorganic layer has a dielectric loss tangent at 10 GHz (or higher frequency) of less than 6×10⁻³, less than 5×10⁻³, less than 4×10⁻³, less than 3×10⁻³, less than 2×10⁻³, less than 1×10⁻³, less than 9×10⁻⁴, less than 8×10⁻⁴, less than 7×10⁻⁴, less than 6×10⁻⁴, less than 5×10⁻⁴, less than 4×10⁻⁴, less than 3×10⁻⁴, less than 2×10⁻⁴, less than 1×10⁻⁴, less than 9×10⁻⁵, less than 8×10⁻⁵, less than 7×10⁻⁵, less than 6×10⁻⁵, less than 5×10⁻⁵, less than 4×10⁻⁵, less than 3×10⁻⁵, less than 2×10⁻⁵, or less than 1×10⁻⁵, or any range thereinbetween. In some embodiments, the inorganic layer has a dielectric loss tangent at 10 GHz (or higher frequency) of about 6×10⁻³, about 5×10⁻³, about 4×10⁻³, about 3×10⁻³, about 2×10⁻³, about 1×10⁻³, about 9×10⁻⁴, about 8×10⁻⁴, about 7×10⁻⁴, about 6×10⁻⁴, about 5×10⁻⁴, about 4×10⁻⁴, about 3×10⁻⁴, about 2×10⁻⁴, about 1×10⁻⁴, about 9×10⁻⁵, about 8×10⁻⁵, about 7×10⁻⁵, about 6×10⁻⁵, about 5×10⁻⁵, about 4×10⁻⁵, about 3×10⁻⁵, about 2×10⁻⁵, or about 1×10⁻⁵, or any intermediate value therein.

In some embodiments, the inorganic layer has a dielectric constant of equal to or less than 10.0, equal to or less than 9.5, equal to or less than 9.0, equal to or less than 8.5, equal to or less than 8.0, equal to or less than 7.5, equal to or less than 7.0, equal to or less than 6.5, equal to or less than 6.0, equal to or less than 5.5, equal to or less than 5.0, equal to or less than 4.5, equal to or less than 4.0, equal to or less than 3.5, equal to or less than 3.0, equal to or less than 2.5, equal to or less than 2.0, equal to or less than 1.5, or equal to or less than 1.0, or any range therein. In some embodiments, the inorganic layer has a dielectric constant of about 10.0, 9.9, 9.8, 9.7, 9.6, 9.5, 9.4, 9.3, 9.2, 9.1, 9.0, 8.9, 8.8, 8.7, 8.6, 8.5, 8.4, 8.3, 8.2, 8.1, 8.0, 7.9, 7.8, 7.7, 7.6, 7.5, 7.4, 7.3, 7.2, 7.1, 7.0, 6.9, 6.8, 6.7, 6.6, 6.5, 6.4, 6.3, 6.2, 6.1, 6.0, 5.9, 5.8, 5.7, 5.6, 5.5, 5.4, 5.3, 5.2, 5.1, 5.0, 4.9, 4.8, 4.7, 4.6, 4.5, 4.4, 4.3, 4.2, 4.1, 4.0, 3.9, 3.8, 3.7, 3.6, 3.5, 3.4, 3.3, 3.2, 3.1, 3.0, 2.9, 2.8, 2.7, 2.6, 2.5, 2.4, 2.3, 2.2, 2.1, 2.0, 1.9, 1.8, 1.7, 1.6, 1.5, 1.4, 1.3, 1.2, or 1.0, or any value thereinbetween.

In some embodiments, the inorganic layer has a porosity of no greater than 50%, no greater than 45%, no greater than 40%, no greater than 35%, no greater than 30%, no greater than 25%, no greater than 20%, no greater than 15%, no greater than 10%, no greater than 5%, no greater than 4%, no greater than 3%, no greater than 2%, no greater than 1%, no greater than 0.9%, no greater than 0.8%, no greater than 0.7%, no greater than 0.6%, no greater than 0.5%, no greater than 0.4%, no greater than 0.3%, no greater than 0.2%, or no greater than 0.1%, or any range therein. In a particular embodiment, the porosity of the one or more inorganic layers is no greater than 1%. In some embodiments, the porosity of the one or more inorganic layers is about 0.1%, about 0.2%, about 0.3%, about 0.4%, about 0.5%, about 0.6%, about 0.7%, about 0.8%, about 0.9%, about 1%, about 2%, about 3%, about 4%, about 5%, about 10%, about 20%, about 30%, about 40%, or about 50%.

Silica-Based Layers or Alumina-Based Layers

In some embodiments, the one or more inorganic layers of the present disclosure may comprise 100 wt. % Al₂O₃ (alumina) or a combination of alumina and silica. In some embodiments, the one or more inorganic layers may contain alumina at a concentration of between about 1 wt. % and about 100 wt. %, between about 5 wt. % and 95 wt. %, between about 10 wt. % and about 90 wt. %, between about 20 wt. % and about 80 wt. %, between about 30 wt. % and about 70 wt. %, between about 40 wt. % and about 60 wt. %, or between about 45 wt. % and about 55 wt. %, relative to the total weight of the inorganic layer, or any ranges therein. In some embodiments, the one or more inorganic layers may contain alumina at a concentration of about 1 wt. %, about 2 wt. %, about 3 wt. %, about 4 wt. %, about 5 wt. %, about 6 wt. %, about 7 wt. %, about 8 wt. %, about 9 wt. %, about 10 wt. %, about 15 wt. %, about 20 wt. %, about 25 wt. %, about 30 wt. %, about 35 wt. %, about 40 wt. %, about 45 wt. %, about 50 wt. %, about 55 wt. %, about 60 wt. %, about 65 wt. %, about 70 wt. %, about 75 wt. %, about 80 wt. %, about 85 wt. %, about 90 wt. %, about 95 wt. %, about 96 wt. %, about 97 wt. %, about 98 wt. %, about 99 wt. %, or about 100 wt. % alumina, relative to the total weight of the inorganic layer, or any values thereinbetween.

In some embodiments, the one or more inorganic layers of the present disclosure may comprise 100 wt. % silica. In some embodiments, the one or more inorganic layers may contain silica at a concentration of between about 1 wt. % and about 100 wt. %, between about 5 wt. % and 95 wt. %, between about 10 wt. % and about 90 wt. %, between about 20 wt. % and about 80 wt. %, between about 30 wt. % and about 70 wt. %, between about 40 wt. % and about 60 wt. %, or between about 45 wt. % and about 55 wt. %, relative to the total weight of the inorganic layer, or ranges therein. In some embodiments, the one or more inorganic layers may contain silica at a concentration of about 1 wt. %, about 2 wt. %, about 3 wt. %, about 4 wt. %, about 5 wt. %, about 6 wt. %, about 7 wt. %, about 8 wt. %, about 9 wt. %, about 10 wt. %, about 15 wt. %, about 20 wt. %, about 25 wt. %, about 30 wt. %, about 35 wt. %, about 40 wt. %, about 45 wt. %, about 50 wt. %, about 55 wt. %, about 60 wt. %, about 65 wt. %, about 70 wt. %, about 75 wt. %, about 80 wt. %, about 85 wt. %, about 90 wt. %, about 95 wt. %, about 96 wt. %, about 97 wt. %, about 98 wt. %, about 99 wt. %, or about 100 wt. %, relative to the total weight of the inorganic layer, or any value thereinbetween.

Glass-Ceramic Layers

By way of non-limiting example, an inorganic layer according to the present disclosure may comprise a glass-ceramic layer. Non-limiting examples of such glass-ceramic layers are boron-phosphate glass ceramics, as described in PCT International Application No. PCT/US2019/024461, which is hereby incorporated by reference in its entirety, and magnesium aluminosilicate glass ceramics, as described in PCT International Application No. PCT/US2019/040928, which is hereby incorporated by reference in its entirety.

Boron-Phosphate Glass Ceramics

In some embodiments, an inorganic layer according to the present disclosure may be formed from a boron-phosphate glass-ceramic composition which includes: from about 35 mol % to about 75 mol % SiO₂; from about 10 mol % to about 40 mol % B₂O₃; from about 10 mol % to about 40 mol % P₂O₅; and an optional addition of one or more of CaO, MgO and Bi₂O₃ from about 0 mol % to about 5 mol %.

In some embodiments, a boron-phosphate glass ceramic further comprises a boron-phosphate B(PO₄) crystalline phase. The crystalline phase, according to some embodiments, can be derived from a ceramming process that can involve heating the glass-ceramic between about 750° C. and about 1150° C. for about 1 to about 10 hours, as described in PCT International Application No. PCT/US2019/024461.

In some embodiments, a boron-phosphate glass-ceramic layer includes: from about 55 mol % to about 75 mol % SiO₂; from about 10 mol % to about 30 mol % B₂O₃; from about 10 mol % to about 35 mol % P₂O₅; and each of CaO, MgO and Bi₂O₃ from about 0 mol % to about 5 mol %.

According to some embodiments of the boron-phosphate glass-ceramic layers, the total amount of MgO, CaO and Bi₂O₃ is less than or equal to about 5 mol %, in other embodiments, less than or equal to about 2 mol % and, in particular embodiments, the glass-ceramic is substantially free of alkaline earth modifiers.

With further regard to the glass-ceramic compositions of the disclosure, the amount of SiO₂ in the glass-ceramics of the disclosure ranges from about 30 mol % to about 80 mol %, in other embodiments, from about 35 mol % to about 75 mol % and, in particular embodiments, from about 55 mol % to about 75 mol %. As such, the amount of SiO₂ can range from about 30 mol % to about 80 mol %, from about 30 mol % to about 75 mol %, from about 30 mol % to about 70 mol %, from about 40 mol % to about 80 mol %, from about 40 mol % to about 75 mol %, from about 40 mol % to about 70 mol %, from about 50 mol % to about 80 mol %, from about 50 mol % to about 75 mol %, from about 50 mol % to about 70 mol %, from about 55 mol % to about 80 mol %, from about 55 mol % to about 75 mol %, from about 55 mol % to about 70 mol %, and all SiO₂ amounts between these levels.

Referring again to the boron-phosphate glass-ceramic compositions of the disclosure, network formers, B₂O₃ and P₂O₅, are included in these compositions to ensure the formation of a stable glass (prior to the development of crystals). By mixing these network formers in appropriate concentrations with SiO₂, it is possible to achieve a stable bulk glass, while minimizing the need for additional network modifiers, such as alkali metals oxides.

In some embodiments, the amount of B₂O₃ in the boron-phosphate glass-ceramics of the disclosure ranges from about 5 mol % to about 50 mol %, in other embodiments, from about 10 mol % to about 40 mol % and, in particular embodiments, from about 10 mol % to about 30 mol %. As such, the amount of B₂O₃ can range from about 5 mol % to about 50 mol %, from about 5 mol % to about 40 mol %, from about 5 mol % to about 30 mol %, from about 10 mol % to about 50 mol %, from about 10 mol % to about 40 mol %, from about 10 mol % to about 30 mol %, from about 15 mol % to about 50 mol %, from about 15 mol % to about 40 mol %, from about 15 mol % to about 30 mol %, and all B₂O₃ amounts between these levels.

The amount of P₂O₅ in the glass-ceramics of the disclosure ranges from about 5 mol % to about 50 mol %, in other embodiments, from about 10 mol % to about 40 mol % and, in particular embodiments, from about 10 mol % to about 35 mol %. As such, the amount of P₂O₅ can range from about 5 mol % to about 50 mol %, from about 5 mol % to about 40 mol %, from about 5 mol % to about 35 mol %, from about 10 mol % to about 50 mol %, from about 10 mol % to about 40 mol %, from about 10 mol % to about 35 mol %, from about 15 mol % to about 50 mol %, from about 15 mol % to about 40 mol %, from about 15 mol % to about 35 mol %, and all P₂O₅ amounts between these levels.

According to some embodiments of the glass-ceramics of the disclosure, Al₂O₃ can be included from about 0.005 mol % to about 1 mol %. In some embodiments, Al₂O₃ can be included from about 0.005 mol % to about 0.5 mol %, from about 0.005 mol % to about 0.05 mol %, and all values of Al₂O₃ between these amounts.

According to some embodiments of the glass-ceramics of the disclosure, one or more alkaline earth oxides, such as MgO, CaO and SrO, and/or other metal oxides, such as Bi₂O₃, can be added in amounts from 0 mol % to about 5 mol %. These metal oxides can improve the melting behavior of the glass-ceramic compositions of the disclosure. In some embodiments, the total amount of MgO, CaO and Bi₂O₃ is less than or equal to about 5 mol %. In other embodiments, alkaline earth oxides are present only in trace contaminant levels (i.e., less than or equal to 100 ppm). In other embodiments, the glass-ceramics are substantially free of alkaline earth oxides.

In some embodiments, the glass-ceramics of the disclosure can include at least one fining agent such as SnO₂, CeO₂, As₂O₃, Sb₂O₃, Cl⁻, F⁻, or the like in small concentrations to aid in reducing or otherwise eliminating gaseous inclusions during melting. In some embodiments, the glass-ceramic can comprise from about 0.005 mol % to about 0.7 mol % SnO₂, from about 0.005 mol % to about 0.5 mol % SnO₂, or from 0.005 mol % to about 0.2 mol % SnO₂.

Magnesium Aluminosilicate Glass-Ceramics

In some embodiments, an inorganic layer according to the present disclosure may be formed from a magnesium aluminosilicate glass-ceramic composition which comprises network formers SiO₂, Al₂O₃, and MgO. In some embodiments, SiO₂ may be present in a range of 40 mol. % to 80 mol. %, or in a range of 45 mol. % to 75 mol. %, or in a range of 50 mol. % to 70 mol. % (e.g., 58 mol. %), or in a range of 55 mol. % to 65 mol. %, or in a range of 60 mol. % to 70 mol. %. In some embodiments, Al₂O₃ may be present in a range of 5 mol. % to 20 mol. %, or in a range of 8 mol. % to 17 mol. %, or in a range of 10 mol. % to 15 mol. % (e.g., 14 mol. %), or in a range of 9 mol. % to 12 mol. %. In some embodiments, MgO may be present in a range of 5 mol. % to 20 mol. %, or in a range of 8 mol. % to 17 mol. %, or in a range of 7 mol. % to 12 mol. %, or in a range of 10 mol. % to 15 mol. % (e.g., 14 mol. %).

In some embodiments of a magnesium aluminosilicate glass-ceramic, SiO₂ may be present in a range of 40 mol. % to 80 mol. %, Al₂O₃ may be present in a range of 5 mol. % to 20 mol. %, and MgO may be present in a range of 5 mol. % to 20 mol. %. In some examples, SiO₂ may be present in a range of 55 mol. % to 75 mol. %, Al₂O₃ may be present in a range of 9 mol. % to 15 mol. %, and MgO may be present in a range of 7 mol. % to 15 mol. %. In some examples, SiO₂ may be present in a range of 60 mol. % to 70 mol. %, Al₂O₃ may be present in a range of 10 mol. % to 15 mol. %, and MgO may be present in a range of 10 mol. % to 15 mol. %. In some examples, SiO₂ may be present in a range of 60 mol. % to 70 mol. %, Al₂O₃ may be present in a range of 9 mol. % to 12 mol. %, and MgO may be present in a range of 7 mol. % to 12 mol. %. In some examples, SiO₂ may be present in a range of 55 mol. % to 65 mol. %, Al₂O₃ may be present in a range of 10 mol. % to 15 mol. %, and MgO may be present in a range of 10 mol. % to 15 mol. %.

In some embodiments, the magnesium aluminosilicate glass-ceramic comprises at least one of B₂O₃, ZnO, and TiO₂. In some embodiments, a magnesium aluminosilicate glass-ceramic comprises at least two of B₂O₃, ZnO, and TiO₂.

In some embodiments of a magnesium aluminosilicate glass-ceramic, B₂O₃ may be present in a range of 0 mol. % to 10 mol. %, or in a range of 1 mol. % to 8 mol. %, or in a range of 2 mol. % to 5 mol. %, or in a range of 2 mol. % to 3 mol. %. In some examples, ZnO may be present in a range of 0 mol. % to 10 mol. %, or in a range of 1 mol. % to 8 mol. %, or in a range of 3 mol. % to 6 mol. %, or in a range of 4 mol. % to 5 mol. %. In some examples, TiO₂ may be present in a range of 0 mol. % to 10 mol. %, or in a range of 1 mol. % to 9 mol. %, or in a range of 3 mol. % to 7 mol. %, or in a range of 5 mol. % to 6 mol. %.

In some embodiments of a magnesium aluminosilicate glass-ceramic, B₂O₃ may be present in a range of 0 mol. % to 10 mol. % (e.g., 0 mol. %), ZnO may be present in a range of 3 mol. % to 6 mol. % (e.g., 5 mol. %), and TiO₂ may be present in a range of 3 mol. % to 7 mol. % (e.g., 6 mol. %). In some embodiments, B₂O₃ may be present in a range of 2 mol. % to 5 mol. % (e.g., 2.8 mol. % or 3 mol. %), ZnO may be present in a range of 3 mol. % to 6 mol. % (e.g., 4.4 mol. % or 5 mol. %), and TiO₂ may be present in a range of 3 mol. % to 7 mol. % (e.g., 5.3 mol. % or 6 mol. %).

In some embodiments, the magnesium aluminosilicate glass-ceramic comprises a crystalline phase at a concentration in a range of 5 wt. % to 80 wt. % of the glass-ceramic. In some examples, the crystalline phase is in a range of 10 wt. % to 75 wt. %, or in a range of 20 wt. % to 65 wt. %, or in a range of 25 wt. % to 50 wt. %, or in a range of 35 wt. % to 50 wt. %. In some examples, the crystalline phase is in a range of 5 wt. % to 75 wt. %, or in a range of 5 wt. % to 50 wt. %, or in a range of 5 wt. % to 40 wt. %, or in a range of 5 wt. % to 30 wt. %, or in a range of 5 wt. % to 25 wt. %, or in a range of 5 wt. % to 15 wt. %, or in a range of 5 wt. % to 10 wt. %.

In some examples, the magnesium aluminosilicate crystalline phase comprises at least one of MgAl₂O₄/ZnAl₂O₄, MgTiO₅, TiO₂, MgSiO₃, ZrO₂, Mg₂Al₄Si₅O₁₈, Mg-stuffed κ-quartz, or SiO₂. In some examples, the magnesium aluminosilicate crystalline phase comprises at least two of MgAl₂O₄/ZnAl₂O₄, MgTiO₅, TiO₂, MgSiO₃, ZrO₂, Mg₂Al₄Si₅O₁₈, Mg-stuffed β-quartz, or SiO₂. In some examples, the magnesium aluminosilicate crystalline phase comprises at least three of MgAl₂O₄/ZnAl₂O₄, MgTiO₅, TiO₂, MgSiO₃, ZrO₂, Mg₂Al₄Si₅O₁₈, Mg-stuffed β-quartz, or SiO₂. In some examples, the magnesium aluminosilicate crystalline phase comprises at least MgAl₂O₄/ZnAl₂O₄ and MgTiO₅. In some examples, the magnesium aluminosilicate crystalline phase may further comprise ZrO₂; TiO₂; SiO₂; MgSiO₃; TiO₂ and ZrO₂; TiO₂ and MgSiO₃; ZrO₂ and MgSiO₃; TiO₂, MgSiO₃, and Mg₂Al₄Si₅O₁₈; TiO₂, MgSiO₃, and Mg-stuffed β-quartz; or TiO₂, MgSiO₃, Mg₂Al₄Si₅O₁₈, and Mg-stuffed β-quartz. In some examples, the Mg-stuffed β-quartz comprises a MgO to Al₂O₃ to SiO₂ ratio in a range of 1:1:2 to 1:1:8.

Low-Loss Glass Layers

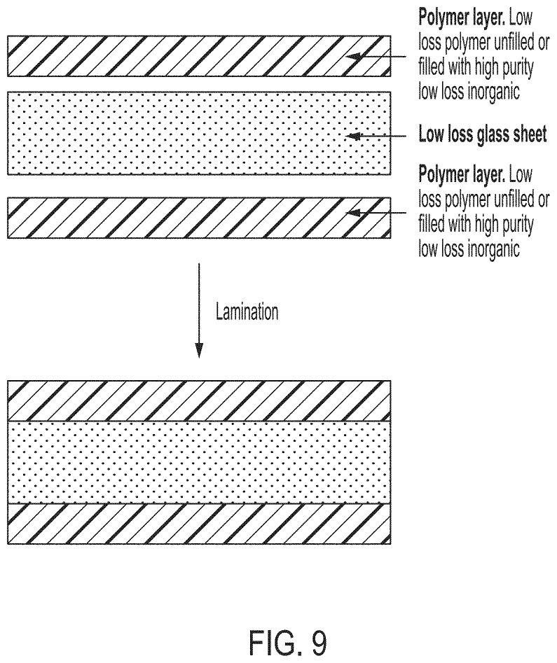

Referring now to FIG. 9, in some embodiments, an inorganic layer according to the present disclosure may comprise a low-loss glass layer. Such glass compositions have been described in U.S. Provisional Patent Application No. 62/794,869, which is hereby incorporated by reference in its entirety. By way of non-limiting example, the loss-loss glasses may have compositions as described herein.

The glasses of the present disclosure may include SiO₂, B₂O₃, and optionally Al₂O₃. The amounts of SiO₂, B₂O₃, and Al₂O₃, can be present in the glasses according to a specified ratio of B₂O₃:(Al₂O₃+SiO₂). For example, the glasses of the present disclosure can have a ratio of B₂O₃:(Al₂O₃+SiO₂) of about 0.22 to about 0.35. In some embodiments, the glass further includes one or more alkaline earth oxides (RO), where RO is CaO, MgO, BaO, and/or SrO. Optionally, the glass can include additional components, such as a fining agent. In some implementations, the glass includes no more than trace amounts of alkali metal oxides and is thus substantially free of alkali metals. As used herein, trace amounts or substantially free refers to amounts of less than 0.5 mol %. In some embodiments, alkali metal oxides and/or alkali metals are present in amounts of less than 0.1 mol %, preferably less than 0.01%.

The glass can include SiO₂ in an amount of from about 60% by mole of oxide (mol %) to about 80 mol %. In some aspects, the amount of SiO₂ can be in the range of about 64 mol % to about 75 mol %, about 60 mol % to about 75 mol %, about 60 mol % to about 70 mol %, about 60 mol % to about 65 mol %, about 65 mol % to about 70 mol %, about 65 mol % to about 75 mol %, about 65 mol % to about 80 mol %, about 70 mol % to about 75 mol %, about 70 mol % to about 80 mol %, or about 75 mol % to about 80 mol %. In some aspects, the amount of SiO₂ can be about 68 mol %, about 69 mol %, about 70 mol %, about 71 mol %, about 72 mol %, about 73 mol %, about 74 mol %, or about 75 mol %.

The glass can include B₂O₃ in an amount of from about 0 mol % to about 28 mol %. In some aspects, the amount of B₂O₃ can be in the range of about 15 mol % to 28 mol %, about 16 mol % to about 26 mol %, about 15 mol % to about 25 mol %, about 15 mol % to about 20 mol %, about 15 mol % to about 18 mol %, about 20 mol % to about 28 mol %, about 20 mol % to about 26 mol %, about 20 mol % to about 24 mol %, or about 20 mol % to about 22 mol %. In some aspects, the amount of B₂O₃ can be about 16 mol %, about 17 mol %, about 18 mol %, about 19 mol %, about 20 mol %, about 21 mol %, about 22 mol %, about 23 mol %, about 24 mol %, or about 25 mol %.

The glass can include Al₂O₃ in an amount of from 0 mol % to about 13 mol %. In some aspects, the amount of Al₂O₃ is in the range of about 1 mol % to about 12 mol %, about 0.1 mol % to about 13 mol %, about 1 mol % to about 13 mol %, about 1 mol % to about 10 mol %, about 1 mol % to about 7 mol %, about 1 mol % to about 5 mol %, about 1 mol % to about 3 mol %, about 3 mol % to about 13 mol %, about 3 mol % to about 10 mol %, about 3 mol % to about 7 mol %, about 3 mol % to about 5 mol %, about 5 mol % to about 13 mol %, about 5 mol % to about 10 mol %, about 5 mol % to about 7 mol %, about 7 mol % to about 13 mol %, about 7 mol % to about 10 mol %, or about 10 mol % to about 13 mol %. In some aspects, the amount of Al₂O₃ is about 1 mol %, about 2 mol %, about 3 mol %, about 4 mol %, about 5 mol %, about 6 mol %, about 7 mol %, or about 8 mol %.

The amounts of SiO₂, B₂O₃, and optionally Al₂O₃ can be selected according to the present disclosure to balance the desired dielectric properties and formability of the glass. In some implementations, the amounts of SiO₂, B₂O₃, and Al₂O₃ are selected such that a ratio of B₂O₃:(Al₂O₃+SiO₂) is from about 0.22 to about 0.35. In some aspects, the ratio of B₂O₃:(Al₂O₃+SiO₂) is from about 0.22 to about 0.24, about 0.29 to about 0.34, about 0.28 to about 0.35, about 0.22 to about 0.3, about 0.22 to about 0.28, about 0.22 to about 0.26, about 0.24 to about 0.35, about 0.24 to about 0.3, about 0.24 to about 0.28, about 0.26 to about 0.35, or about 0.26 to about 0.3. In some aspects, the ratio of B₂O₃:(Al₂O₃+SiO₂) is about 0.22, about 0.23, about 0.24, about 0.29, about 0.30, about 0.31, about 0.32, about 0.33, or about 0.34.

In some embodiments, the amounts of SiO₂ and B₂O₃ are selected such that a sum of SiO₂ plus B₂O₃ is from about 84 mol % to about 97 mol %. In some aspects, the sum of SiO₂ plus B₂O₃ is from about 85 mol % to about 97 mol %, about 86 mol % to about 97 mol %, about 86 mol % to about 94 mol %, about 86 mol % to about 90 mol %, about 86 mol % to about 88 mol %, about 90 mol % to about 97 mol %, about 90 mol % to about 94 mol %, about 93 mol % to about 97 mol %, or about 94 mol % to about 97 mol %. In some embodiments, the sum of SiO₂ plus B₂O₃ is about 86 mol %, about 87 mol %, or about 88 mol %.

In some embodiments, the amounts of SiO₂, B₂O₃, and Al₂O₃ are selected such that a sum of SiO₂ plus B₂O₃ plus Al₂O₃ is from about 88 mol % to about 100 mol %, about 89 mol % to about 100 mol %, about 90 mol % to about 100 mol %, about 91 mol % to about 100 mol %, or from about 92 mol % to about 100 mol %. In some aspects, the sum of SiO₂ plus B₂O₃ plus Al₂O₃ is from about 92 mol % to about 95 mol %, from about 92 mol % to about 98 mol %, from about 95 mol % to about 100 mol %, from about 95 mol % to about 98 mol %, from about 96 mol % to about 100 mol %, or from about 96 mol % to about 98 mol %. In some aspects, the sum of SiO₂ plus B₂O₃ plus Al₂O₃ is about 92 mol %, about 93 mol %, about 94 mol %, or about 95 mol %.

When present, the low-loss glass can include one or more alkaline earth oxides (RO), where RO is CaO, MgO, BaO, and/or SrO. In some embodiments, the one or more alkaline earth oxides are present in an amount of from 0 mol % to about 12 mol %, about 0 mol % to about 10 mol %, about 0 mol % to about 12 mol %, about 0.1 mol % to about 12 mol %, about 2 mol % to about 12 mol %, about 3 mol % to about 12 mol %, about 4 mol % to about 12 mol %, about 5 mol % to about 12 mol %, about 6 mol % to about 12 mol %, about 7 mol % to about 12 mol %, about 8 mol % to about 12 mol %, about 9 mol % to about 12 mol %, about 10 mol % to about 12 mol %, about 11 mol % to about 12 mol %, about 2 mol % to about 4 mol %, about 2 mol % to about 6 mol %, about 4 mol % to about 8 mol %, or about 5 mol % to about 8 mol %. In some aspects, the one or more alkaline earth oxides are present in an amount of about 2 mol %, about 2.5 mol %, about 4 mol %, about 6 mol %, about 6.5 mol %, about 7 mol %, or about 7.5 mol %, about 8 mol %, about 8.5 mol %, about 9 mol %, about 9.5 mol %, about 10 mol %, about 10.5 mol %, about 11 mol %, about 11.5 mol %, or about 12 mol %.

In some embodiments, the low-loss glass includes CaO and MgO. In some embodiments, CaO is present in an amount of from 0 mol % to about 7 mol %, from about 0 mol % to about 6 mol %, or from about 0 mol % to about 5 mol %, and MgO is present in an amount of from about 1 mol % to about 7 mol %, about 1 mol % to about 6 mol %, about 1 mol % to about 5 mol %, from about 1 mol % to about 4 mol %, or about 1 mol % to about 3.5 mol %. In some aspects, CaO is present in an amount of from 0 mol % to about 7 mol %, about 0.1 mol % to about 7 mol %, about 0.5 mol % to about 7 mol %, about 1 mol % to about 7 mol %, about 2 mol % to about 7 mol %, about 3 mol % to about 7 mol %, about 4 mol % to about 7 mol %, about 5 mol % to about 7 mol %, about 6 mol % to about 7 mol %, about 0.5 mol % to about 4 mol %, about 1 mol % to about 4 mol %, about 1 mol % to about 3 mol %, or about 1 mol % to about 2 mol % in combination with MgO present in an amount of from about 1 mol % to about 5 mol %, about 1 mol % to about 4.5 mol %, about 1 mol % to about 4 mol %, about 1 mol % to about 3.5 mol %, about 1 mol % to about 3 mol %, about 1 mol % to about 2.5 mol %, about 1 mol % to about 2 mol %, about 1.5 mol % to about 5 mol %, about 1.5 mol % to about 4.5 mol %, about 1.5 mol % to about 4 mol %, about 1.5 mol % to about 3.5 mol %, about 1.5 mol % to about 3 mol %, about 1.5 mol % to about 2.5 mol %, about 1.5 mol % to about 2 mol %, about 2 mol % to about 3.5 mol %, about 2 mol % to about 3 mol %, about 2.5 mol % to about 3.5 mol %, or about 2.5 mol % to about 3 mol %. In some embodiments, MgO is present at a concentration of about 1 mol %, about 1.5 mol %, about 2.0 mol %, about 2.5 mol %, about 3.0 mol %, about 3.5 mol %, about 4.0 mol %, about 4.5 mol %, or about 5.0 mol %.

The amount of alkaline earth oxides can be selected in concert with other materials, such as B₂O₃ and optionally Al₂O₃ to provide glasses having the desired characteristics. For example, increasing the amount of alkaline earth oxides relative to SiO₂ and Al₂O₃ can have the effect of decreasing the viscosity of a glass melt and may increase melting and forming temperatures. Alkaline earth oxides may also increase the coefficient of thermal expansion (“CTE”) and density of the glass, and may affect other properties as well, such as the elastic modulus. Alkaline earth oxides can also decrease the liquidus temperature. Thus, the amounts of the alkaline earth oxides, B₂O₃, and Al₂O₃ can be selected according to the present disclosure to balance the desired physical properties and formability of the glass.

In some implementations, the amounts of alkaline earth oxides, B₂O₃, and Al₂O₃ are selected such that a ratio of RO:(Al₂O₃+(0.5*B₂O₃)) is from about 0 to about 0.8, about 0 to about 0.7, about 0 to about 0.6, or about 0 to about 0.5. In some aspects, the ratio of RO:(Al₂O₃+(0.5*B₂O₃)) is from about 0 to about 0.8, about 0 to about 0.7, about 0 to about 0.6, about 0 to about 0.5, about 0 to about 0.4, about 0 to about 0.3, about 0.1 to about 0.8, about 0.1 to about 0.7, about 0.1 to about 0.6, about 0.1 to about 0.5, about 0.1 to about 0.4, about 0.1 to about 0.3, about 0.1 to about 0.2, about 0.2 to about 0.8, about 0.2 to about 0.7, about 0.2 to about 0.6, about 0.2 to about 0.5, about 0.2 to about 0.4, about 0.2 to about 0.3, about 0.3 to about 0.5, about 0.3 to about 0.4, about 0.4 to about 0.5, about 0.5 to about 0.6, about 0.6 to about 0.7, or 0.7 to about 0.8. In some aspects, the ratio of RO:(Al₂O₃+(0.5*B₂O₃)) is about 0.2, about 0.3, about 0.4, about 0.5, about 0.6, about 0.7, or about 0.8.

The glasses of the present disclosure may optionally include one or more fining agents, such as, by way of non-limiting example, SnO₂, Sb₂O₃, As₂O₃, and/or one or more halogen salts, including fluorine, chlorine, or bromine salts. When a fining agent is present in the glass composition, the fining agent may be present in a total amount less than about 1 mol %. In some aspects, the fining agent is present in an amount of about 0.01 mol % to about 1 mol %, about 0.01 mol % to about 0.5 mol %, about 0.01 mol % to about 0.25 mol %, about 0.01 mol % to about 0.1 mol %, about 0.05 mol % to about 0.1 mol %, about 0.05 mol % to about 0.25 mol %, about 0.05 mol % to about 0.5 mol %, or about 0.05 mol % to about 1 mol %. In some aspects, the fining agent is present in an amount of about 0.08 mol %, about 0.09 mol %, or about 0.1 mol %. When the content of the fining agent is too large, the fining agent may enter the glass structure and affect various glass properties. However, when the content of the fining agent is too low, the glass may be difficult to form. According to one aspect of the disclosure, SnO₂ is included as a fining agent in an amount of 0 to about 0.1 mol %.

The glass may optionally include contaminants or unintended additives, such as TiO₂. These additional materials, when present, are typically present in very low or trace amounts of less than 0.5 mol %.

Inorganic Fabrics/Weaves

In some embodiments, an inorganic layer of the PCB laminate material is a ceramic or glass fabric (or “weave”). For example, in some embodiments, the inorganic layer comprises a silica fabric, weave, or chopped fiber. Non-limiting examples of ceramic or glass fabrics include Astroquartz®, Astroquartz II®, or Astroquartz III® (JPS Composite Materials).

### Filled (“Infiltrated”) Layers

Filled (“Infiltrated”) Inorganic Layers

Referring again to FIGS. 1-2, in some embodiments, PCB laminates according to the present disclosure comprise an inorganic layer (e.g., a porous silica scaffold, a ceramic, etc.) further comprising at least one polymer powder. The polymer powder may function as a filler and enhances the toughness of the inorganic layer, and PCB laminate materials prepared therefrom, while not significantly affecting the thermal properties and dimensional stability. These materials have been described in WIPO Publication No. 2019/083893A1, which is hereby incorporated by reference in its entirety.

In some embodiments, the inorganic material may be any suitable inorganic material, preferably one of the inorganic materials discussed above (e.g., silica-based materials, alumina-based materials, ceramics, glass-ceramics, glasses, low-loss glasses, or combinations thereof). In some embodiments, the inorganic material may be present at a concentration of at least 50 wt. % to about 99 wt. %, about 55 wt. % to about 95 wt. %, about 60 wt. % to about 90 wt. %, about 65 wt. % to about 85 wt. %, or about 70 wt. % to about 80 wt. %, or any range or value therein. In an embodiment, the inorganic material is present at a concentration of about 70 wt. % to about 90 wt. %. In some embodiments, the inorganic material is present at a concentration of about 50 wt. %, about 55 wt. %, about 60 wt. %, about 65 wt. %, about 70 wt. %, about 75 wt. %, about 80 wt. %, about 85 wt. %, about 90 wt. %, about 95 wt. %, about 96 wt. %, about 97 wt. %, about 98 wt. %, or about 99 wt. %, or any value thereinbetween.

In some embodiments, the inorganic material of the infiltrated inorganic layer has a porosity of no greater than 50%, no greater than 45%, no greater than 40%, no greater than 35%, no greater than 30%, no greater than 25%, no greater than 20%, no greater than 15%, no greater than 10%, no greater than 5%, no greater than 4%, no greater than 3%, no greater than 2%, no greater than 1%, no greater than 0.9%, no greater than 0.8%, no greater than 0.7%, no greater than 0.6%, no greater than 0.5%, no greater than 0.4%, no greater than 0.3%, no greater than 0.2%, or no greater than 0.1%, or any range therein. In a particular embodiment, the porosity of the inorganic material of the infiltrated inorganic layer is no greater than 1%. In some embodiments, the porosity of the inorganic material of the infiltrated inorganic layer is about 0.1%, about 0.2%, about 0.3%, about 0.4%, about 0.5%, about 0.6%, about 0.7%, about 0.8%, about 0.9%, about 1%, about 2%, about 3%, about 4%, about 5%, about 10%, about 20%, about 30%, about 40%, or about 50%.

In some examples, the at least one polymer powder is selected from cyclic olefin copolymers (“COCs”) (e.g., the Topas® COC polymers, APEL®, Zeonor®, Zeonex®, ARTON®), polystyrene polymers (PS), polyetheretherketone polymers (PEEK), polyetherimide polymers (PEI), liquid crystal polymers, polypropylene polymers, cyclic olefins, linear olefins, bi-cyclic olefin norbornene, ethylene, polyisobutylene, 4-methylpentene, (dimethyl) polyphenyloxide (PPO), or combinations thereof.

In some embodiments, the at least one polymer powder is present at a concentration of 1 wt. % to 50 wt. %, or 5 wt. % to 45 wt. %, or 10 wt. % to 40 wt. %, or 15 wt. % to 35 wt. %, or 20 wt. % to 30 wt. %, or 21 wt. % to 29 wt. %, or 22 wt. % to 28 wt. %, or 23 wt. % to 27 wt. %, or 24 wt. % to 26 wt. %, or any range or value therein. In some examples, the at least one polymer powder is present at a concentration of at least 1 wt. %, or 2 wt. %, or 5 wt. %, or 10 wt. %, or 15 wt. %, or 20 wt. %, or 25 wt. %, or 30 wt. %, or 35 wt. %, or 40 wt. %, or 45 wt. %, or 50 wt. %, or 55 wt. %, or 60 wt. %, or 65 wt. %, or 70 wt. %, or 75 wt. %, or 80 wt. %, or 85 wt. %, or 90 wt. %, or 95 wt. %, or 100 wt. %, or any value therein.

Filled (“Infiltrated”) Polymer Layers

Referring again to FIG. 2, in some embodiments, PCB laminates according to the present disclosure comprise a polymer layer (e.g., a low-loss polymer or copolymer layer, a fluoropolymer layer, a composite polymer layer, etc.) further comprising at least one inorganic powder. The inorganic powder may function as a filler and enhances the thermal properties and dimensional stability of the polymer layer, and PCB laminate materials made therefrom, while not significantly affecting the dielectric loss tangent.

In some examples, the at least one polymer powder is selected from cyclic olefin copolymers (“COCs”) (e.g., the Topas® COC polymers, APEL®, Zeonor®, Zeonex®, ARTON®), polystyrene polymers (PS), polyetheretherketone polymers (PEEK), polyetherimide polymers (PEI), liquid crystal polymers, polypropylene polymers, cyclic olefins, linear olefins, bi-cyclic olefin norbornene, ethylene, polyisobutylene, 4-methylpentene, (dimethyl) polyphenyloxide (PPO), or combinations thereof.

In some embodiments, the infiltrated polymer layer may comprise any suitable polymer material, preferably one of the polymer materials discussed above (e.g., low-loss polymers or co-polymers, fluoropolymers, composite polymers, etc.). In some embodiments, the polymer material may be present at a concentration of at least 50 wt. % to about 99 wt. %, about 55 wt. % to about 95 wt. %, about 60 wt. % to about 90 wt. %, about 65 wt. % to about 85 wt. %, or about 70 wt. % to about 80 wt. %, or any range or value therein. In an embodiment, the polymer material is present at a concentration of about 70 wt. % to about 90 wt. %. In some embodiments, the inorganic material is present at a concentration of about 50 wt. %, about 55 wt. %, about 60 wt. %, about 65 wt. %, about 70 wt. %, about 75 wt. %, about 80 wt. %, about 85 wt. %, about 90 wt. %, about 95 wt. %, about 96 wt. %, about 97 wt. %, about 98 wt. %, or about 99 wt. %, or any value thereinbetween.

In some examples, the at least one inorganic powder is selected from silica (SiO₂), alumina (Al₂O₃), alumina trihydrate (Al₂O₃.3H₂O), antimony oxide (Sb₂O₃, Sb₂O₅, Sb₂O₄), barium sulfate (BaSO₄), calcium carbonate (CaCO₃), kaolinite (Al₂Si₂O₅(OH)₄), magnesium hydroxide (Mg(OH)₂), talc (Mg₃Si₄O₁₀(OH)₂), titanium dioxide (TiO₂), or combinations thereof. In an embodiment, the at least one inorganic powder is silica (SiOₓ).

In some examples, the at least one inorganic powder is present at a concentration within the range of 1 wt. % to 50 wt. %, or 5 wt. % to 45 wt. %, or 10 wt. % to 40 wt. %, or 15 wt. % to 35 wt. %, or 20 wt. % to 30 wt. %, or any range or value therein. In some examples, the at least one inorganic powder may comprise silica including SiOₓ in an amount of at least 1 wt. %, or 2 wt. %, or 5 wt. %, or 10 wt. %, or 15 wt. %, or 20 wt. %, or 25 wt. %, or 30 wt. %, or 35 wt. %, or 40 wt. %, or 45 wt. %, or 46 wt. %, or 47 wt. %, or 48 wt. %, or 49 wt. %, or 50 wt. %, or any value thereinbetween. In some examples, the infiltrated polymer layer may comprise at least one inorganic powder present in a range of 0 wt. % to 25.0 wt. %, or 0 wt. % to 10.0 wt. %, or 0.01 wt. % to 20.0 wt. %, or 0.05 wt. % to 17.5 wt. %, or 0.10 wt. % to 15.0 wt. %, or 0.25 wt. % to 12.5 wt. %, or 0.50 wt. % to 10.0 wt. %, or 0.75 wt. % to 7.5 wt. %, or 1.0 wt. % to 7.0 wt. %, or 1.5 wt. % to 6.5 wt. %, or 2.0 wt. % to 6.0 wt. %, or 2.5 wt. % to 5.5 wt. %, or 3.0 wt. % to 5.0 wt. %, or any range or value therein.

### Adhesion Promoters

In another aspect, which may be combined with any of the other aspects or embodiments of the present disclosure, the PCB laminate material according to the present disclosure further comprises one or more adhesion promoters that promote bonding of one or more inorganic layers to one or more polymer layers, fluoropolymer layers, or inorganic layers. In some embodiments, the one or more adhesion promoters is selected from (but not limited to) silane, amine, diamine, dipodal, vinyl, combinations thereof, or other coupling agents. In a particular embodiment, the adhesion promoter is 3-aminopropyltriethoxysilane (APTES). In a particular embodiment, the adhesion promoter may be applied from a solution comprising water, isopropanol (or ethanol, methanol, etc.), and acetic acid.

### Stacked Laminates

Referring to FIGS. 1-4, 6, 7, and 9, in another aspect, which may be combined with any other aspects or embodiments, the PCB laminate materials of the present disclosure are “stacked” multilayered laminate materials, including (i) one or more polymer layers, and (ii) one or more inorganic layers and/or one or more fluoropolymer layers. It is believed that the presence of multiple layers within the composite material enhances the fracture toughness when compared to single-layer materials of the same thickness, which are more prone to cracking, chipping, and ablation. In some embodiments, the PCB laminate materials comprise at least 2, at least 3, at least 4, at least 5, at least 6, at least 7, at least 8, at least 9, at least 10, at least 11, at least 12, at least 13, at least 14, or at least 15 layers, or any range therein. In some embodiments, the PCB laminate materials have 2, 3, 4, 5, 6, 7, 8, 9, 10, 11, 12, 13, 14, or 15, or more layers. The PCB laminate materials may comprise any combination or order of polymer layers (e.g., low-loss polymers or copolymers, fluoropolymers, composite polymers), inorganic layers (ceramics, glass-ceramics, glasses, low-loss glasses, inorganic fabrics or weaves, etc.), and/or infiltrated layers.

In some embodiments the total thickness of the PCB laminate material is between 80 μm and 1.7 mm, between 100 μm and 1.5 mm, between 120 μm and 1.3 mm, between 150 μm and 1 mm, between 200 μm and 800 μm, between 300 μm and 600 μm, or between 400 μm and 500 μm, or any range therein. In some embodiments, the total thickness of the PCB laminate material is about 60 μm, about 70 μm, about 80 μm, about 90 μm, about 100 μm, about 110 μm about 120 μm, about 130 μm, about 140 μm, about 150 μm, about 160 μm, about 170 μm, about 180 μm, about 200 μm, about 250 μm, about 300 μm, about 350 μm, about 400 μm, about 450 μm, about 500 μm, about 550 μm, about 600 μm, about 650 μm, about 700 μm, about 750 μm, about 800 μm, about 850 μm, about 900 μm, about 950 μm, about 1 mm, about 1.1 mm, about 1.2 mm, about 1.3 mm, about 1.4 mm, about 1.5 mm, about 1.6 mm, or about 1.7 mm, or any value thereinbetween.

In some embodiments, the PCB laminate materials according to the present disclosure have a dielectric loss tangent suitable for use in high-frequency (e.g., 10 GHz or higher frequency) applications. In some embodiments, the PCB laminate materials have a dielectric loss tangent at 10 GHz (or higher frequency) of less than 5×10⁻³, less than 4×10⁻³, less than 3×10⁻³, less than 2×10⁻³, less than 1×10⁻³, less than 9×10⁻⁴, less than 8×10⁻⁴, less than 7×10⁻⁴, less than 6×10⁻⁴, less than 5×10⁻⁴, less than 4×10⁻⁴, less than 3×10⁻⁴, less than 2×10⁻⁴, or less than 1×10⁻⁴, less than 9×10⁻⁵, less than 8×10⁻⁵, less than 7×10⁻⁵, less than 6×10⁻⁵, less than 5×10⁻⁵, less than 4×10⁻⁵, less than 3×10⁻⁵, less than 2×10⁻⁵, or less than 1×10⁻⁵. In some embodiments, the PCB laminate material has a dielectric loss tangent at 10 GHz (or higher frequency) of about 1×10⁻⁵, about 2×10⁻⁵, about 3×10⁻⁵, about 4×10⁻⁵, about 5×10⁻⁵, about 6×10⁻⁵, about 7×10⁻⁵, about 8×10⁻⁵, about 9×10⁻⁵, about 1×10⁻⁴, about 2×10⁻⁴, about 3×10⁻⁴, about 4×10⁻⁴, about 5×10⁻⁴, about 6×10⁻⁴, about 7×10⁻⁴, about 8×10⁻⁴, about 9×10⁻⁴, about 1×10⁻³, about 2×10⁻³, about 3×10⁻³, about 4×10⁻³, or about 5×10⁻³.

In some embodiments, the PCB laminate material has a dielectric constant of less than 15.0, less than 14.0, less than 13.0, less than 12.0, less than 11.0, less than 10.0, less than 9.5, less than 9.0, less than 8.5, less than 8.0, less than 7.5, less than 7.0, less than 6.5, less than 6, less than 5.5, less than 5, less than 4.5, less than 4.0, less than 3.5, less than 3, less than 2.5, or less than 2, at a measurement frequency of, e.g., 10 GHz (or higher frequency). In some embodiments, the PCB laminate material has a dielectric constant of about 10.0, 9.9, 9.8, 9.7, 9.6, 9.5, 9.4, 9.3, 9.2, 9.1, 9.0, 8.9, 8.8, 8.7, 8.6, 8.5, 8.4, 8.3, 8.2, 8.1, 8.0, 7.9, 7.8, 7.7, 7.6, 7.5, 7.4, 7.3, 7.2, 7.1, 7.0, 6.9, 6.8, 6.7, 6.6, 6.5, 6.4, 6.3, 6.2, 6.1, 6.0, 5.9, 5.8, 5.7, 5.6, 5.5, 5.4, 5.3, 5.2, 5.1, 5.0, 4.9, 4.8, 4.7, 4.6, 4.5, 4.4, 4.3, 4.2, 4.1, 4.0, 3.9, 3.8, 3.7, 3.6, 3.5, 3.4, 3.3, 3.2, 3.1, 3.0, 2.9, 2.8, 2.75, 2.7, 2.6, 2.5, 2.4, 2.3, 2.2, 2.1, 2.0, 1.9, 1.8, 1.7, 1.6, 1.5, 1.4, 1.3, 1.2, or 1.0, or any value thereinbetween. In an embodiment, the PCB laminate material has a dielectric constant of less than 3.5 at a measurement frequency of, e.g., 10 GHz (or higher frequency).

In some embodiments, the PCB laminate material of the present disclosure has a fracture toughness sufficient to permit laser drilling through the PCB laminate material of 30-μm to 100-μm holes without fracturing or developing defects. In some embodiments, the PCB laminate material has a fracture toughness of at least 0.2 K_{Ic} (MPa·m^{0.5}), at least 0.3 K_{Ic} (MPa·m^{0.5}), at least 0.4 K_{Ic} (MPa·m^{0.5}), at least 0.5 K_{Ic} (MPa·m^{0.5}), at least 0.6 K_{Ic} (MPa·m^{0.5}), at least 0.7 K_{Ic} (MPa·m^{0.5}), at least 0.8 K_{Ic} (MPa·m^{0.5}), at least 0.9 K_{Ic} (MPa·m^{0.5}), at least 1.0 K_{Ic} (MPa·m^{0.5}), at least 1.1 K_{Ic} (MPa·m^{0.5}), at least 1.2 K_{Ic} (MPa·m^{0.5}), at least 1.3 Kip (MPa·m^{0.5}), at least 1.4 K_{Ic} (MPa·m^{0.5}), or at least 1.5 Kip (MPa·m^{0.5}), or any range or value therein. In an embodiment, the PCB laminate material has a fracture toughness of at least 0.9 K_{Ic} (MPa·m^{0.5}).

In some embodiments, a PCB laminate material according to the present disclosure has a flexural modulus of about 1 GPa to about 400 GPa, about 2 GPa to about 350 GPa, about 3 GPa to about 300 GPa, about 4 GPa to about 250 GPa, about 5 GPa to about 200 GPa, about 6 GPa to about 150 GPa, about 7 GPa to about 100 GPa, about 8 GPa to about 80 GPa, about 9 GPa to about 70 GPa, or about 10 GPa to about 60 GPa. In some embodiments, a PCB laminate material according to the present disclosure has a flexural modulus of about 1 GPa, 2 GPa, 3 GPa, 4 GPa, 5 GPa, 6 GPa, 7 GPa, 8, GPa, 9 GPa, 10 GPa, 11 GPa, 12 GPa, 13 GPa, 14 GPa, 15 GPa, 20 GPa, 25 GPa, 30 GPa, 35 GPa, 40 GPa, 45 GPa, 50 GPa, 55 GPa, 60 GPa, 65 GPa, 70 GPa, 75 GPa, 80 GPa, 85 GPa, 90 GPa, 95 GPa, 100 GPa, 110 GPa, 120 GPa, 130 GPa, 140 GPa, 150 GPa, 160 GPa, 170 GPa, 180 GPa, 190 GPa, 200 GPa, 250 GPa, 300 GPa, 350 GPa, or 400 GPa, or any value thereinbetween.

In some embodiments, a PCB laminate material according to the present disclosure has a flexural strength of about 20 MPa to about 400 MPa, about 25 MPa to about 350 MPa, about 30 MPa to about 300 MPa, about 35 MPa to about 250 MPa, about 40 MPa to about 200 MPa, about 45 MPa to about 180 MPa, or about 50 MPa to about 150 MPa, or any range therein. In some embodiments, a PCB laminate material according to the present disclosure has a flexural strength of about 20 MPa, about 25 MPa, about 30 MPa, about 35 MPa, about 40 MPa, about 45 MPa, about 50 MPa, about 55 MPa, about 60 MPa, about 65 MPa, about 70 MPa, about 75 MPa, about 80 MPa, about 85 MPa, about 90 MPa, about 95 MPa, about 100 MPa, about 110 MPa, about 115 MPa, about 120 MPa, about 125 MPa, about 130 MPa, about 135 MPa, about 140 MPa, about 150 MPa, about 160 MPa, about 170 MPa, about 180 MPa, about 190 MPa, about 200 MPa, about 250 MPa, about 300 MPa, about 350 MPa, or about 400 MPa, or any value thereinbetween.

The PCB laminate material of the present disclosure is free of or contains only trace water or other impurities which may impair its dielectric or mechanical performance. For example, in some embodiments, the water content of the PCB laminate material is less than 0.5 wt-%, less than 0.4 wt-%, less than 0.3 wt-%, less than 0.2 wt-%, preferably less than 0.1 wt-%.

In some embodiments, the PCB laminate material contains very low concentrations, and preferably no, alkali metals and/or alkaline earth metals. In some embodiments, the concentration of alkali metals and alkaline earth metals in the PCB laminate material is less than 500 ppm, less than 400 ppm, less than 300 ppm, less than 200 ppm, less than 100 ppm, less than 90 ppm, less than 80 ppm, less than 70 ppm, less than 60 ppm, less than 50 ppm, less than 40 ppm, less than 30 ppm, less than 25 ppm, less than 20 ppm, less than 15 ppm, less than 10 ppm, less than 5 ppm, or less than 1 ppm. In an embodiment, the concentration of alkali metals and alkaline earth metals in the PCB laminate material is less than 25 ppm.

### Printed Circuit Boards

A printed circuit board (PCB) typically consists of an insulating layer between two films of a conductive cladding (e.g., copper cladding), though some applications use only one film of such conductive cladding. The conductive cladding layers are typically laminated to the insulating layer.

The PCB laminate materials described above, in any of their aspects or embodiments, can be used as the insulating layer or layers of a PCB to produce PCBs with good dielectric performance (i.e., low dielectric loss), dimensional stability at elevated temperature (e.g., at 260° C. for 30 seconds), sufficient mechanical strength to permit handling during production (e.g., via drilling) without damage, burr, or fracture, good adhesion, and fire resistance.

A PCB according to the present disclosure may include any of the aspects or embodiments discussed above. By way of non-limiting example, in some embodiments, PCBs according to the present disclosure comprise (a) a PCB laminate material having a first side and a second side, the PCB laminate material comprising (i) a polymer layer, and (ii) an inorganic layer, and (b) at least one conductive layer (e.g., copper) laminated onto the first side of the PCB laminate material. In some embodiments, the PCBs of the present disclosure comprise a second conductive layer (e.g., copper) laminated onto the second side of the PCB laminate material.

In some embodiments, PCBs according to the present disclosure may include PCB laminate materials that possess any combination of the electrical, structural, mechanical, or other properties discussed in the Description above and the Examples below. For example, in some embodiments, a PCB according to the present disclosure includes a PCB laminate material having a dielectric loss tangent of no greater than 0.005 at 10 GHz (or higher frequency). As another example, a PCB according to the present disclosure includes an inorganic layer having a thickness of 200 μm or less, or 100 μm or less.

As further non-limiting examples, in some embodiments, a PCB according to the present disclosure includes an inorganic layer which comprises a glass layer having a dielectric loss tangent of less than or equal to 0.006 at 10 GHz (or higher frequency) and/or a thickness of 100 μm or less and/or a porosity of 1% or less.

The present disclosure also contemplates methods of making PCBs comprising the PCB laminate materials of the present disclosure. By way of non-limiting example, a method of making a PCB according to the present disclosure comprises (a) contacting a polymer layer with a second layer selected from an inorganic layer, a fluoropolymer layer, or a polymer layer; (b) laminating the polymer layer to the second layer to produce a PCB laminate material; and (c) laminating the PCB laminate material to at least one conductive cladding layer, wherein step (b) comprises heating the polymer layer and the second layer.

Methods of making PCBs according to the present disclosure may comprise laminating any of aspects or embodiments of PCB laminate materials discussed in the Description above or the Examples below to one or more conductive cladding layers (e.g., copper) to produce a PCB.

Embodiments according to the present disclosure will be described more fully hereinafter. Aspects of the disclosure may, however, be embodied in different forms and should not be construed as limited to the embodiments set forth herein. Rather, these embodiments are provided so that this disclosure will be thorough and complete, and will fully convey the scope of the technology to those skilled in the art.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the present application and relevant art and should not be interpreted in an idealized or overly formal sense unless expressly so defined herein. While not explicitly defined below, such terms should be interpreted according to their common meaning.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like, include the number recited and refer to ranges which can be subsequently broken down into subranges as discussed above. Finally, as will be understood by one skilled in the art, a range includes each individual member. Thus, for example, a group having 1-3 layers refers to groups having 1, 2, or 3 layers. Similarly, a group having 1-5 layers refers to groups having 1, 2, 3, 4, or 5 layers, and so forth.

Unless the context indicates otherwise, it is specifically intended that the various features of the invention described herein can be used in any combination. Moreover, the disclosure also contemplates that in some embodiments, any feature or combination of features set forth herein can be excluded or omitted. To illustrate, if the specification states that a complex comprises components A, B and C, it is specifically intended that any of A, B or C, or a combination thereof, can be omitted and disclaimed singularly or in any combination.

Unless explicitly indicated otherwise, all specified embodiments, features, and terms intend to include both the recited embodiment, feature, or term and biological equivalents thereof.

All patents, patent applications, provisional applications, and publications referred to or cited herein are incorporated by reference in their entirety, including all figures and tables, to the extent they are not inconsistent with the explicit teachings of this specification.

The following examples are given for the purpose of illustrating various embodiments of the disclosure and are not meant to limit the present disclosure in any fashion. One skilled in the art will appreciate readily that the present disclosure is well adapted to carry out the objects and obtain the ends and advantages mentioned, as well as those objects, ends and advantages inherent herein. The present examples, along with the methods described herein are presently representative of embodiments and are exemplary, and are not intended as limitations on the scope of the disclosure. Changes therein and other uses which are encompassed within the spirit of the disclosure as defined by the scope of the claims will occur to those skilled in the art. It is to be understood that this present technology is not limited to particular methods, reagents, compounds compositions or biological systems, which can, of course, vary. The terminology used in the description herein is for the purpose of describing particular embodiments only and is not intended to be limiting.

### EXAMPLES

### Example 1: Procedure for Producing 22-m²/g Amorphous Silica Green Tape Sheet

Amorphous silica green tape is prepared from a slip that is both non-aqueous and slightly polar to non-polar. It includes methoxy propyl acetate (MPA), polyvinyl butyral binder (PVB), dibutyl phthalate plasticizer (DP) and Menhaden fish oil (MFO) dispersant. MPA is an ether acetate solvent with a vapor pressure of 2.5 mmHg and a density of 0.980 g/cm³. It is an excellent solvent for PVB binder system due to the similarity of ether and acetate functional groups.

Butvar B79 was selected as the PVB binder for this slip because of its relatively low polarity and its relatively good solubility. This is due to its low concentration of hydroxyl groups (˜11-13%, in the form of polyvinyl alcohol) relative to acetate groups (polyvinyl acetate). It also has a low molecular weight (50,000 g/mol to 80,000 g/mol) relative to other PVB binder systems, enabling a reduced slip viscosity and higher solids loadings.

Dibutyl phthalate plasticizer was used to lower the glass transition temperature of the slip to approximately −3.5° C. The storage modulus of the green tape thus prepared is 4.83×10⁸ Pa.

The MFO dispersant includes several different fatty acids and enables good dispersion of metal oxide powders by modifying the surface charge and/or by steric hindrance to prevent metal oxide particle aggregation. This enables production of a well-dispersed slip with uniform composition and high solids loading. The slip thus prepared is well-suited to tape casting and enables casting of silica tapes ranging in thickness from about 4 μm to about 230 μm.

To prepare the slip, oxide powders (e.g., silica powder, alumina powder, nanophase alumina, etc.) are first dispersed in MPA and MFO using a Mazerustar mixer. After the oxide powders are well-dispersed, the PVB and DP are added, and the mixture is again dispersed using the Mazerustar mixer. The entire slip is then attrition milled for 2 hours with 2-mm YTZ media at 1000-2000 rpm. The attrition step reduces agglomeration but does not reduce particle size significantly. After milling, the system is rolled overnight to de-air before tape-casting.

The tape is cast either in a batch process or a continuous process. Due to the low vapor pressure of MPA (2.5 mmHg at 20° C.), continuous casting requires heating the tape caster to 60° C. in order to achieve the highest yields. Without heating, the tape is cast in a batch process and requires several hours to dry. In either case, the tape is defect-free and uniform in composition and thickness.

Tables 1 and 2 below show the slip compositions and tape compositions for tapes prepared from nominally 21 m²/g 100-nm fused silica powder and nanophase alumina powder respectively.

TABLE 1
Slip and tape compositions for 21 m²/g 100-nm fused silica powder.

| | Mass | Density | Volume | Slip Vol. | Tape Vol. | Tape Mass |
|---|---|---|---|---|---|---|
| Component | (g) | (g/ml) | (ml) | Fraction | Fraction | Fraction |
| BF-21 m²/g silica | 173.000 | 2.200 | 78.636 | 0.178 | 0.576 | 0.742 |
| 100% Methoxy | 300.000 | 0.980 | 306.122 | 0.692 | — | — |
| Propyl Acetate | | | | | | |
| PVB Butvar B-79 | 42.800 | 1.060 | 40.377 | 0.091 | 0.296 | 0.184 |
| Dispersant Fish Oil | 7.300 | 0.930 | 7.849 | 0.018 | 0.058 | 0.031 |
| (Z1) | | | | | | |
| Dibutyl Phthalate | 10.100 | 1.050 | 9.619 | 0.022 | 0.070 | 0.043 |

TABLE 2
Slip and Tape Compositions for Nanophase Alumina

| | Mass | Density | Volume | Slip Vol. | Tape Vol. | Tape Mass |
|---|---|---|---|---|---|---|
| Component | (g) | (g/ml) | (ml) | Fraction | Fraction | Fraction |
| Alpha nano | 180.000 | 3.900 | 46.154 | 0.174 | 0.570 | 0.833 |
| alumina in slip | | | | | | |
| Methoxy Propyl | 180.000 | 0.980 | 183.673 | 0.694 | — | — |
| Acetate in | | | | | | |
| alumina slip | | | | | | |
| 100% Methoxy | 0.000 | 0.980 | 0.000 | 0.000 | — | — |
| Propyl Acetate | | | | | | |
| PVB Butvar B-79 | 25.500 | 1.060 | 24.057 | 0.091 | 0.297 | 0.118 |
| Dispersant Fish | 4.500 | 0.930 | 4.839 | 0.018 | 0.060 | 0.021 |
| Oil (Z1) | | | | | | |
| Dibutyl Phthalate | 6.200 | 1.050 | 5.905 | 0.022 | 0.073 | 0.029 |

### Example 2: Aqueous Slip System for Preparing and Casting Silica Tape

As an alternative to the methods disclosed in Example 1, an aqueous slip system significantly reduces costs associated with manufacturing by eliminating the hazardous solvent-based waste stream and associated explosion-proof equipment and facilities.

The slip system uses an acrylic binder package from Polymer Innovations, Inc. Its stability in water is highly dependent on pH, such that the binder will drop out of solution if the pH drops below 6. This, along with avoidance of silica particle agglomeration, requires that the slip must be maintained at a high pH during processing. The slip thus has a pH of approximately 9-10, due to the addition of ammonium hydroxide and a high pH (˜14) plasticizer (PL005). Table 3 shows aqueous slip compositions for producing the aqueous silica slip.

TABLE 3
Aqueous Slip Composition for Silica Tapes

| | | | | | Slip | | Tape |
|---|---|---|---|---|---|---|---|
| | Mass | Density | Volume | Slip Vol. | Mass | Tape Vol. | Mass |
| Component | (g) | (g/ml) | (ml) | Fraction | Fraction | Fraction | Fraction |
| Silica PL22 | 160.00 | 2.2 | 72.73 | .2144 | .3719 | .6072 | .7676 |
| (22 m²/g) | | | | | | | |
| Binder | 100.00 | 1.03 | 97.09 | .2862 | .2325 | .2837 | .1679 |
| (WB4101) | | | | | | | |
| Sovent | 150.00 | 1 | 150.00 | .4422 | .3487 | — | — |
| (Water) | | | | | | | |
| Dispersant | 8.50 | 1.1 | 7.73 | .0228 | .0198 | 0.0323 | .0204 |
| (DS005) | | | | | | | |
| Plasticizer | 5.00 | 1 | 5.00 | .0147 | .0116 | .0417 | .0240 |
| (PL005) | | | | | | | |
| Defoamer | 4.20 | 1 | 4.20 | .0124 | .0098 | .0351 | .0201 |
| (DF002) | | | | | | | |
| Base | 2.50 | 1 | 2.50 | .0074 | .0058 | — | — |
| (NH₄OH) | | | | | | | |

### Example 3: Aqueous Slip System for Preparing and Casting Alumina Tape

Similar to Example 2, an aqueous slip system provides a potentially safer, cost-effective alternative for production of alumina tapes. Table 4 shows an alumina slip composition for casting alumina tapes.

TABLE 4
Aqueous Slip Composition for Alumina Tapes

| | | | | Slip | | |
|---|---|---|---|---|---|---|
| | Mass | Density | Volume | Vol. | Tape Vol. | Tape Mass |
| Component | (g) | (g/ml) | (ml) | Fraction | Fraction | Fraction |
| Al₂O3 | 2925.00 | 3.96 | 783.64 | .2461 | .6851 | .8933 |
| (sasol) | | | | | | |
| Binder | 903.00 | 1.03 | 876.70 | .2921 | .2846 | 0.0965 |
| (WB4101) | | | | | | |
| Solvent | 1260.00 | 1 | 1260.00 | .4198 | — | — |
| (Water) | | | | | | |
| Dispersant | 57.25 | 1.03 | 55.58 | .0185 | 0.0206 | .0070 |
| (DS001) | | | | | | |
| Defoamer | 10.40 | 1 | 10.40 | .0035 | .0096 | 0.0032 |
| (DF002) | | | | | | |
| Base | 60.00 | 1 | 60.00 | .0200 | — | — |
| (NH₄OH) | | | | | | |

The solvent (water), dispersant (DS001), defoamer (DF002), and binder (WB4101) and ammonia are milled for 15 minutes using a Union Process tank/impeller non-recirculating mill containing alumina media (60 vol. % charge) at 500 rpm. The alumina powder is then added in thirds, milling for 10 minutes at 500 rpm between each addition. After all the alumina powder is added, the mixture is attrition milled for 1 hour at 1000 rpm. This step homogenizes and de-agglomerates the slip (but does not necessarily reduce particle size). After milling, the slip is de-aired in a beaker placed in a vacuum chamber for 12 hours.

Tape casting. The de-aired slip is poured into a reservoir and cast using a doctor blade with a preset gap (e.g., ˜7-12 mil), according to thickness desired, onto the carrier film. The slip is then drawn in a sheet across the casting bed as the carrier film moves. The thin sheet dries as it is carried across the casting bed and is rolled with the carrier film on the take-up spool at the end of the caster. The tape is easily released from the silicone coated Mylar carrier film when the roll is transferred to the continuous sintering process. The casting speed is set to 13 in/min and heaters in zones 1, 2, 3, and 5 are set to 50° C., 50° C., 70° C., and 70° C., respectively.

### Example 4: Procedure for Sintering 22-m²/g Amorphous Silica Green Tape

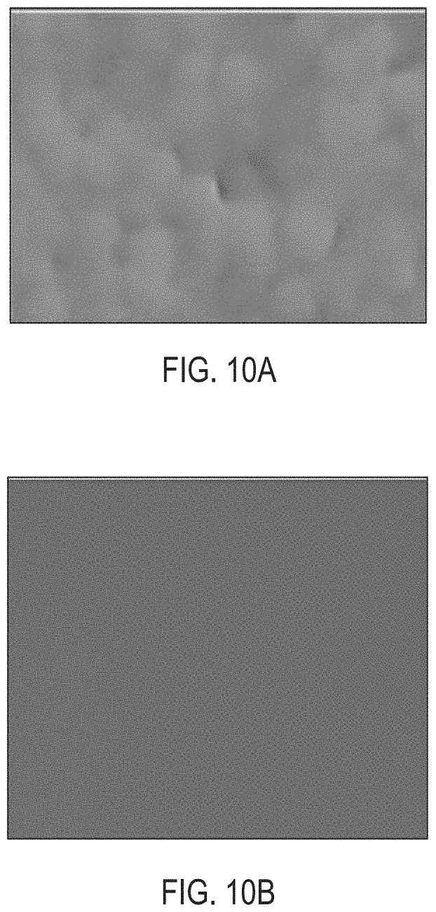

Amorphous silica green tape is sintered using a horizontal continuous sintering process. The silica tape is first subjected to a de-binding process and is then immediately transferred into the sintering zone. Table 5 shows the characteristics of the de-binding process. Sintering is carried out at 1300° C. at 3 in/min to produce a fully-fused silica tape that is transparent and has a low dielectric loss tangent of <0.0001, which can later be incorporated into composite laminates for PCB applications. FIGS. 10A-B show the effect of sintering temperature on surface morphology and porosity for the silica tapes obtained by continuous sintering. The continuously sintered silica tapes are smooth and non-porous.

TABLE 5
Debinding Process Profile for Amorphous Silica Green Tape

| | | | | | | | |
|---|---|---|---|---|---|---|---|
| Zone | 1, 2 | 3, 4 | 5, 6 | 7, 8 | 9, 10 | 11, 12 | Air |
| Temperature | 240 | 300 | 375 | 425 | 510 | 580 | 225 |
| (° C.) | | | | | | | |

### Example 5: Procedure for Producing Porous Silica Sheets

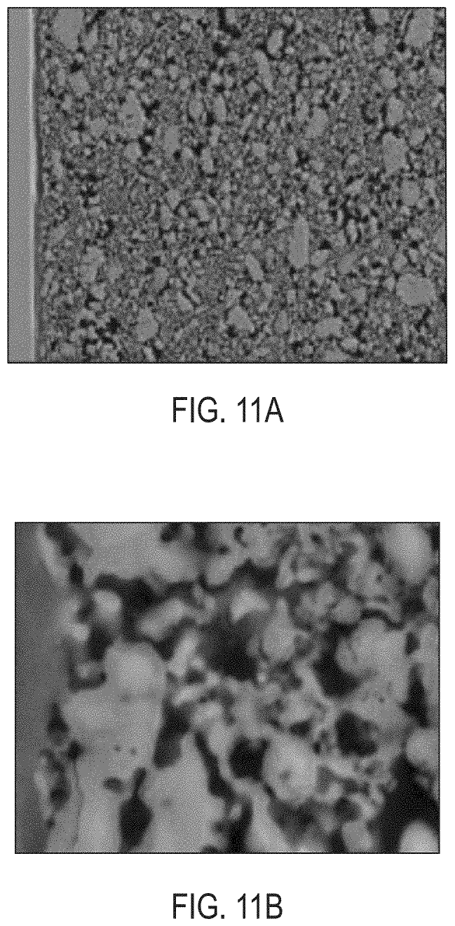

Bisque-fired porous silica sheets can be produced in a manner similar to Example 4, but by reducing the sintering temperature to between 1225° C. and 1275° C. However, to achieve a large enough pore size distribution to effectively infiltrate, the sheet becomes too weak to handle. Therefore, larger silica/quartz particles (e.g., IMSIL A25, ˜5-μm) are used to create a larger pore volume. A small amount of 22 m²/g amorphous silica is also added to reduce the sintering temperature to 1450° C. to avoid cristobalite formation, which occurs when quartz is sintered above 1470° C. FIGS. 11A-B show the increase in porosity for silica sheets thus prepared, when compared to silica sheets prepared according to Example 4 (FIGS. 10A-B).

Table 6 shows the non-polar slip composition used to produce porous silica, which is similar to the slip used for Example 2. Because the surface area of IMSIL is very low, a higher solids loading is possible in the green tape. Samples were sintered to 1450° C. for 30 min.

TABLE 6
Slip and Tape Compositions for Porous Silica

| | Mass | Density | Volume | Slip Vol. | Tape Vol. | Tape Mass |
|---|---|---|---|---|---|---|
| Component | (g) | (g/ml) | (ml) | Fraction | Fraction | Fraction |
| IMSIL A25 | 266.000 | 2.650 | 100.377 | 0.294 | 0.731 | 0.842 |
| (median~5 μm) | | | | | | |
| PL22 (22 m²/g) | 22.000 | 2.200 | 10.000 | 0.029 | 0.073 | 0.070 |
| Total Silica | | | | | 0.804 | 0.911 |
| 100% Methoxy | 200.000 | 0.980 | 204.082 | 0.598 | — | — |
| Propyl Acetate | | | | | | |
| PVB Butvar B-79 | 20.000 | 1.060 | 18.868 | 0.055 | 0.137 | 0.063 |
| Dispersant Fish | 3.000 | 0.930 | 3.226 | 0.009 | 0.024 | 0.009 |
| Oil (Z1) | | | | | | |
| Dibutyl Phthalate | 5.000 | 1.050 | 4.762 | 0.014 | 0.035 | 0.016 |

### Example 6: Electrostatic Spray Process for Preparing Porous Inorganic Layers

As an alternative to the preparative methods described in Examples 1-3, inorganic layers with up to approximately 70% porosity can be prepared by an electrostatic spray process. Electrostatic spraying is a widely used technique in which a dry powder is fluidized by a compressed gas and then charged by an electric field. The charged particles are attracted to a plate that is either grounded or has an opposing charge. The charged particles will adhere to substrates which can be attached to the plate, or they can be deposited directly to the plate. Therefore, the process works best on substrates that are conductive (e.g., Pt foil or Grafoil®) or have a high dielectric constant.

The deposited powder can then be sintered to form dense or porous self-supporting sheets. For example, silica can be sintered at 1400° C. to 1450° C. to form porous silica sheets with approximately 100-μm pores and approximately 70% porosity, as determined by mercury intrusion porosimetry.

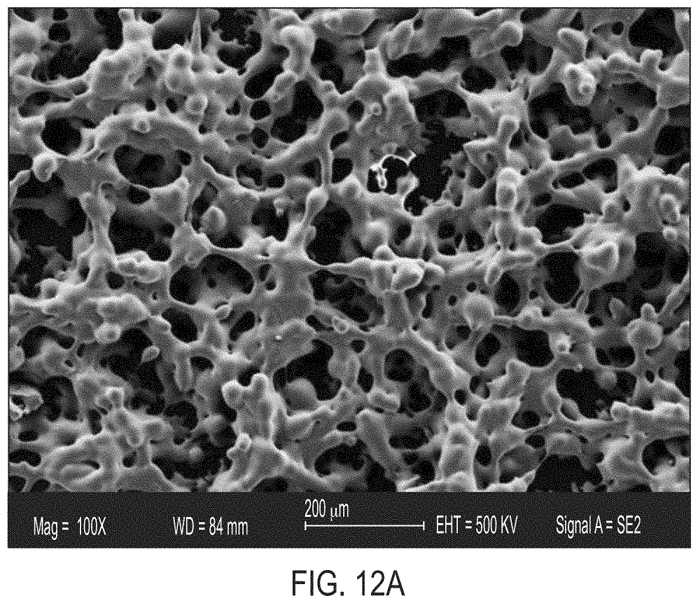

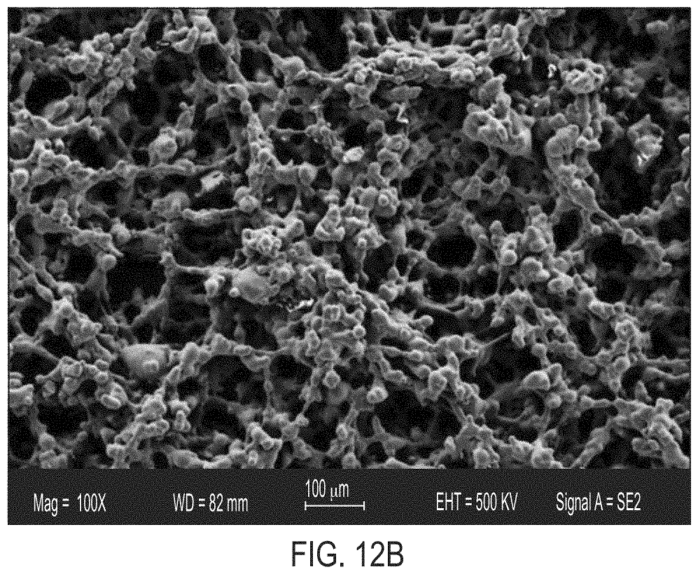

FIG. 12A shows a SEM image of a PL22 porous film formed by electrostatic spraying onto Pt foil. FIG. 12B shows a SEM image of a PL22 porous film formed by electrostatic spraying onto a Grafoil® sheet. The porous glass or ceramic sheets can be released from the substrates, or the porous sheets may serve as coatings for the substrates on which they are formed. This process achieves a sheet with higher uniformity and flatness than standard methods and eliminates the need for processing steps associated with slurries for wet spraying methods or tape casting methods. However, as the powder is deposited, the substrate becomes more and more insulating and therefore there is a limitation to thickness and uniformity. For example, this limit is approximately 1 mm for PL22 porous films.

### Example 7: Tape Casting Procedure for Preparing Polymer Sheets for Laminates

Topas (1 g) is dissolved in 5 g cyclohexane, corresponding to a solids loading of about 16.7 wt-%. The mixture is rolled overnight to permit dissolution and is de-aired under vacuum. The solution is cast on a Teflon carrier film to facilitate easy release upon drying. The polymer sheet can be formed as a smooth or textured sheet by casting upon a smooth or matte Teflon carrier, respectively. Upon drying, a thin sheet of Topas is formed. The polymer sheet is removed by doctor blade technique. The blade width determines the polymer film thickness. For example, 10 mil, 20 mil, and 30 mil blades create 23-μm, 50-μm, or 70-μm green tapes, respectively.

### Example 8: Extrusion Procedure for Polymer Sheets

Polymer pellets are extruded into sheets using an Inch and a Half Davis Standard Extruder equipped with a 10-inch wide film die and heated chrome rollers. For Topas® 8007S and Topas® 6013 S films, the chrome roll temperature is 220° C. and 280° C., respectively. Table 7 below shows extruder conditions (temperature and roll speed) used to create polymer films of 50-μm and 80-μm thickness.

TABLE 7
Roller Temperature and Speed for Extruding Topas ® Films

| Downstream Equipment | 8007S | | 6013S | |
|---|---|---|---|---|
| Conditions | 50 μm | 80 μm | 50 μm | 80 μm |
| Chrome Roll Temp (° C.) | 220 | 220 | 280 | 280 |
| Chrome Roll Speed (rpm) | 232 | 210 | 350 | 250 |
| Pull Roll Speed (rpm) | 234 | 212 | 360 | 260 |

### Example 9: Composite Polymer Preparation

Methods of preparing composite polymers and laminating them into sheets are described in U.S. Provisional Patent Application No. 62/819,852, incorporated by reference in its entirety.

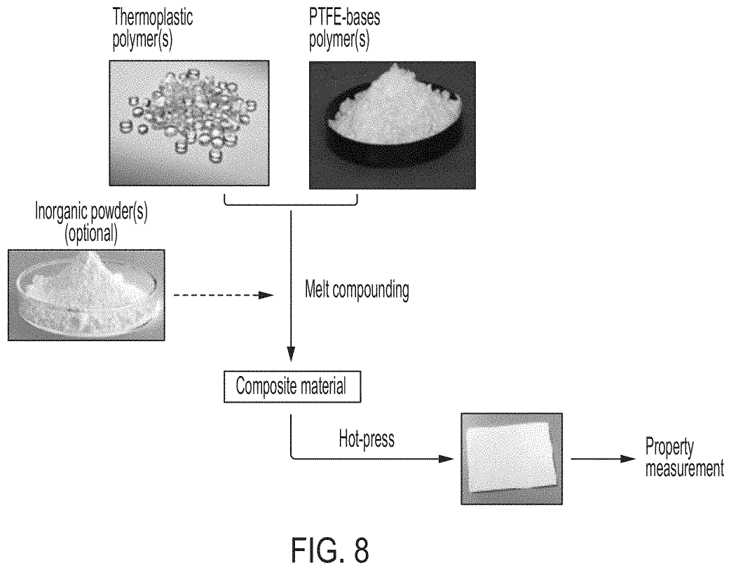

Referring again to FIG. 8, composite polymer layers are prepared by a melt process whereby at least one thermoplastic polymer and at least one PTFE-based polymer are mixed and subsequently melted at a temperature in a range of 150° C. to 350° C. (e.g., 250° C.), or 175° C. to 325° C., or 200° C. to 300° C., or 225° C. to 275° C., or 250° C. to 350° C., or 150° C. to 250° C., or any range or value therein. The melting may be conducted for a time in a range of 1 min to 45 min, or 2 min to 30 min, or 5 min to 25 min, or 10 min to 20 min (e.g., 15 min), or 12.5 min to 17.5 min, or any range or value therein. In some examples, the mixture is prepared with at least one thermoplastic polymer and at least one PTFE-based polymer, with an inorganic layer (e.g., a silica fabric or weave). In some embodiments, the mixture is prepared with at least one inorganic powder. The final composite has a composition (e.g., ratios, weights, etc.) as described above and is determined by the composition of the initial base materials.

The resulting final composite polymer may then be laminated into sheets at a thickness from 50 μm to 1000 μm, or 100 μm to 900 μm, or 150 μm to 850 μm, or 200 μm to 800 μm, or 250 μm to 750 μm, or 300 μm to 700 μm, or 350 μm to 650 μm, or 400 μm to 600 μm, or 450 μm to 550 μm, or any range or value therein by a hot press or other sufficient technique at a temperature in a range of 150° C. to 350° C. (e.g., 230° C.), or 175° C. to 325° C., or 200° C. to 300° C., or 225° C. to 275° C., or 250° C. to 350° C., or 150° C. to 250° C., or any range or value therein.

### Example 10: Procedure for In-Situ Polymerization in Porous Ceramic Scaffolds (“Infiltrated” Inorganic Layers)

Cleaning and surface functionalization of porous ceramic scaffold. Ceramic scaffolds (e.g., porous scaffolds prepared according to Examples 5 and 6) were cleaned and treated with trichloro(1H,1H,2H,2H-perfluorooctyl)silane (97%, Sigma-Aldrich) as an adhesion promoter. The ceramic scaffolds were first ultrasonicated at 70° C. in a diluted Liquinox detergent for 8 minutes followed by SC-1 cleaning at 70° C. The SC-1 solution consists of 15% ammonium hydroxide, 15% hydrogen peroxide and 60% de-ionized water. A solution of 1% trichloro(1H,1H,2H,2H-perfluorooctyl)silane in IPA was prepared, and the SC-1-cleaned scaffolds were ultrasonicated in the solution for 30 minutes, followed by ultrasonication in pure IPA for five minutes. After drying with nitrogen gas, the scaffolds were baked at 120° C. for one hour. The scaffolds were then placed inside a clean reaction vessel connected to a Schlenk line. The inside of the vessel and the scaffold were dried by heating the vessel to 80° C. and actively vacuum pumping the vessel for >14 hours.

Styrene Polymerization. The styrene polymerization procedure is adapted from von Hippel, A. & Wesson, L. G., Polystyrene Plastics as High Frequency Dielectrics, 38 INDUS. & ENG'G CHEM. 1121-29 (1946). The styrene monomer (ReagentPlus®, ≥99%, with 4-tert-butylcatechol as stabilizer, Sigma Aldrich) was dried for 2 days over molecular sieves (5A, powder <50 μm, ACROS Organics) followed by 2 more days over calcium sulfate. The stabilizer was removed through vacuum distillation at 25-35° C. Oxygen was removed from the styrene using a freeze-pump-thaw procedure. Styrene was transferred into the reaction vessel using a cannula transfer procedure to minimize the amount of gas entering the reaction vessel. The styrene wicked into the porous silica scaffold. Finally, the styrene was polymerized in the porous scaffolds by heating the vessel on a hot plate at about 80° C. for 4 days, at 120° C. for two days, and at 150° C. for one more day.

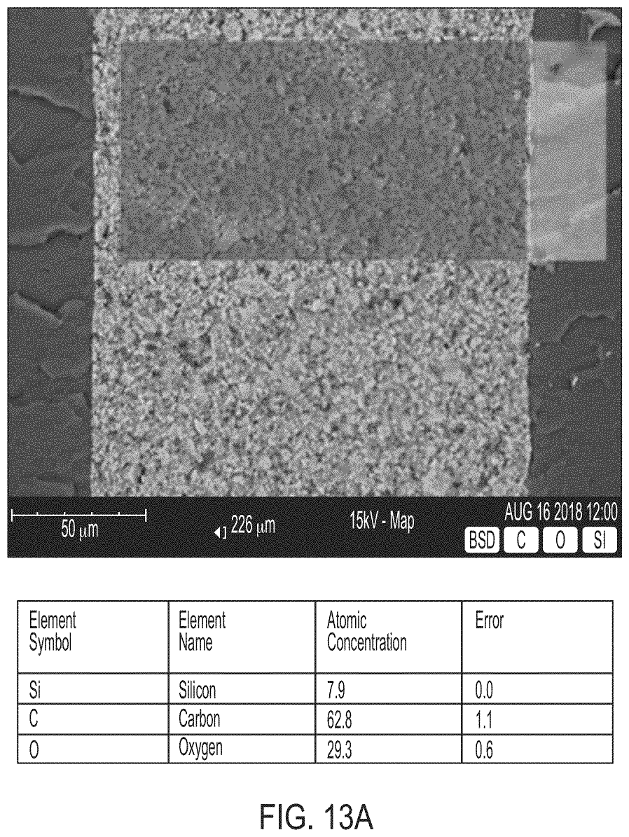

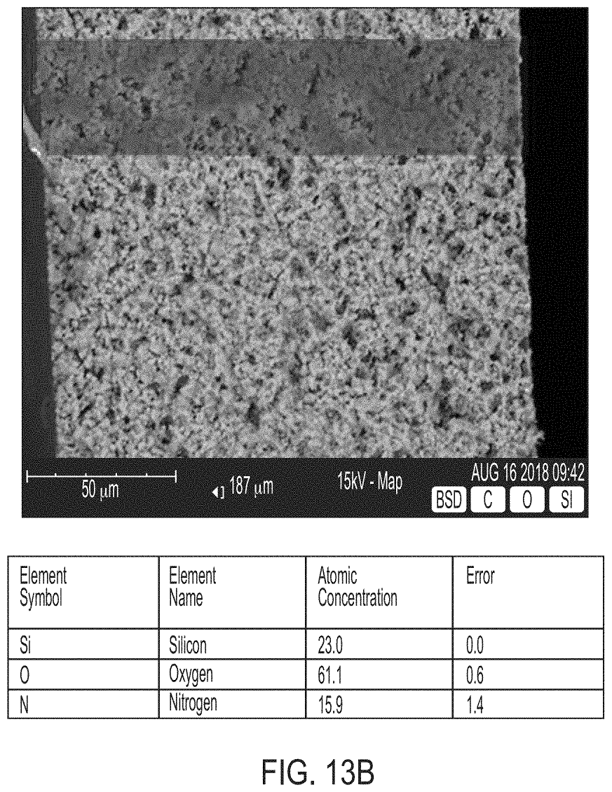

FIGS. 13A-B show SEM images with energy-dispersive x-ray (EDX) data for a polystyrene-infused silica scaffold (FIG. 13A) and a bare porous silica scaffold (FIG. 13B). The data shows the presence of carbon within the silica scaffold, indicating that polystyrene has been polymerized within the pores. Although the present Example discusses infiltrated inorganic layers within the context of porous silica scaffolds infiltrated with polystyrene, the general method described herein is non-limiting, and analogous procedures permit preparation of a broad range of inorganic scaffolds infiltrated with a broad range of polymers.

### Example 11: Procedure for Lamination (3-Layer Laminates)

The process for laminating inorganic layers (e.g., silica, alumina, etc.) to organic layers (e.g., Topas®) uses vacuum conditions to remove air from between the layers, along with heat and pressure to bond the materials together.

Topas® sheets, prepared either by extrusion or tape casting (e.g., according to Examples 7 or 8), are embossed with a de-airing pattern to enable and/or enhance air removal during vacuum application. This step is carried out if the extrusion or tape casting process did not include a surface roughening or patterning step and can be conducted using a flatbed vacuum laminator or in a vacuum bag placed in an oven.

A glass-reinforced Teflon sheet is placed on both sides of the Topas® film to produce the surface pattern. The samples are de-aired under vacuum for approximately 3 minutes, followed by application of 30-50 kPa overpressure for approximately 2 minutes. For Topas® 8007S and Topas® 6013S, this step takes place at 70-75° C. and approximately 160° C., respectively, due to the different T_{g} values for the two materials.

Following vacuum de-airing, the Topas® films are cut to size to match the silica or alumina pieces produced according to the procedures described in Examples 1 and 3. The silica and/or alumina pieces are cleaned using isopropanol and/or 50/50 isopropanol/deionized water applied to a lint-free cloth under semi-cleanroom conditions.

An adhesion promoter is applied to the silica or alumina on the side or sides that will be laminated to the Topas® films. For example, a 0.11 wt-% solution of 3-aminopropyltriethoxysilane (APTES) in isopropanol/water/acetic acid is applied on the silica or alumina surfaces using a lint-free cloth and allowed to dry. Alternatively, the adhesion promoter is applied using a dip coating process followed by an alcohol rinse.

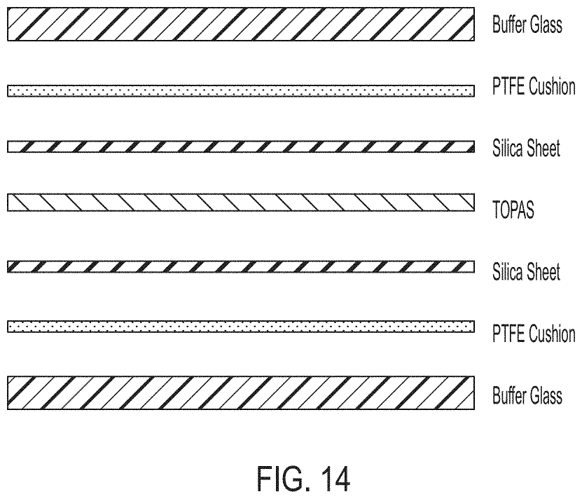

FIG. 14 shows a schematic illustration of the lay-up for preparing one embodiment of three-layer PCB laminate materials (stacks). The individual silica, alumina, and/or Topas® sheets are laid up or assembled in the desired order, and the stack is sandwiched between sheets of a non-stick release material, such as PTFE on a thicker substrate material (e.g., 0.7-mm Gorilla Glass). The stack is secured by tape or other means to maintain alignment.

The assemblies are then inserted into vacuum bags and surround by a release cloth and a breather cloth external to the release cloth to prevent bag collapse. After the vacuum bag is evacuated and heat sealed, the vacuum-bagged assemblies are loaded into an autoclave and secured in place.

The lamination procedure is conducted by ramping the autoclave to a predetermined set point for each polymer (e.g., 130° C. for Topas® 8007-S or 200° C. for Topas® 6013-S, ramped at approximately 3° C./min). The pressure is then ramped to approximately 80 psi at 5 psi/min, and the setpoint conditions are held for approximately 30 minutes. The temperature is then ramped down to less than approximately 50° C. at a rate of −3° C./min, followed by a pressure ramp-down of −5 psi/min to atmospheric pressure. Vacuum conditions within the vacuum bag are maintained throughout the autoclave cycle.

Following the autoclave procedure, the assemblies are removed from the vacuum bagging materials and buffer sheets to produce laminated assemblies.

### Example 12: Alternate Procedure for Lamination (Tape-Casting Method)

Topas® (1 g) is dissolved in 5 g cyclohexane, corresponding to a solids loading of about 16.7 wt-%. The mixture is rolled overnight to permit dissolution and is de-aired under vacuum. A fused silica or alumina tape is placed on a Teflon carrier film to facilitate good releasability upon drying. Upon drying, a thin sheet of Topas® is formed on the fused silica tape. The polymer sheet is removed by doctor blade technique. The blade width determines the polymer film thickness. In this case, the doctor blade width should be selected to account for the silica (or alumina) film thickness. For example, if a 50-μm polymer layer on top of a 50-μm silica layer is desired, then the blade width should be set to 20 mil+20 mil, as a 20 mil blade width creates a 50-μm green tape after the solvent dries.

### Example 13: Calculating the Dielectric Loss Properties of Laminates

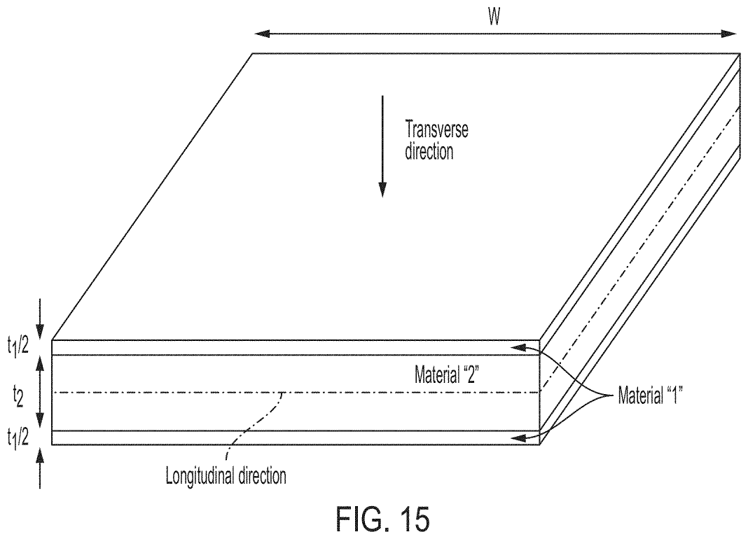

FIG. 15 shows a schematic illustration of a sheet of PCB laminate material comprising two materials: “Material 1” and “Material 2.” The cross section of the laminate is assumed to be symmetrical about the symmetry plane, the total thickness of Material is t₁, and that of Material 2 is t₂. Similarly, the permittivities of the two materials are ε₁ and ε₂, and the dielectric loss tangents are tan δ₁ and tan δ₂, respectively.

The cross section is assumed to be symmetrical (about the symmetry plane). In most cases, there are only two different materials in the composite laminates considered as examples here, but the results given here for dielectric properties may be extended to three or more materials by adding extra terms to the formulae set forth below.

The results given here for effective permeability and loss tangent are calculated under DC conditions. At GHz frequencies, the field distributions will differ from the distributions at DC and so the “effective” permeability and loss tangent of a composite laminate will not have the same values at DC as it has in the GHz regime. However, the DC calculation is simple and gives results that are sufficiently accurate for determining the broad properties of structures made from given materials.

The dielectric properties of the structure are anisotropic. In the longitudinal direction, the structure behaves as three capacitors in parallel. However, in the transverse direction, the structure “looks like” three capacitors in series. These two cases are considered separately. In general, the results are similar (well within a factor of 2) and despite this discrepancy are good enough for the present purpose of broad evaluation.

The longitudinal values may be more appropriate when dealing with split cylinder or split post resonator measurements, and the transverse for strip lines.

Longitudinal Case

The effective permeability is given by

$${ɛ}_{eff} = \frac{{t}_{1} {ɛ}_{1} + {t}_{2} {ɛ}_{2}}{{t}_{1} + {t}_{2}} \qquad ( Equation 1 )$$

If there were three materials in the structure, the effective permeability would be

$${ɛ}_{eff} = \frac{{t}_{1} {ɛ}_{1} + {t}_{2} {ɛ}_{2} + {t}_{3} {ɛ}_{3}}{{t}_{1} + {t}_{2} + {t}_{3}} \qquad ( Equation 2 )$$

The remaining equations can be extended in a similar manner. The effective loss tangent for a two-material composite is

$$tan {δ}_{eff} = \frac{{t}_{1} {ɛ}_{1} tan {δ}_{1} + {t}_{2} {ɛ}_{2} tan {δ}_{2}}{{t}_{1} {ɛ}_{1} + {t}_{2} {ɛ}_{2}} \qquad ( Equation 3 )$$

Transverse Case

In the transverse case, the effective permeability and loss tangent are

$$\begin{matrix}\frac{1}{{ɛ}_{eff}} = \frac{{t}_{1} / {ɛ}_{1} + {t}_{2} / {ɛ}_{2}}{{t}_{1} + {t}_{2}} & ( Equation 4 ) \\ tan {δ}_{eff} = \frac{{t}_{1} / {ɛ}_{1} tan {δ}_{1} + {t}_{2} / {ɛ}_{2} tan {δ}_{2}}{{t}_{1} / {ɛ}_{1} + {t}_{2} / {ɛ}_{2}} & ( Equation 5 )\end{matrix}$$

### Example 14: Dielectric Loss Tangent and Permittivity Measurements

Dielectric performance was assessed using two different instruments. In both cases, the technique relies on the measurement of the change in resonance frequency and Q factor of a microwave cavity before and after the insertion of the sample into the cavity. Knowing the thickness of the sample, the shift in resonance frequency allows its permittivity to be calculated, and the reduction in cavity Q with the sample inside gives its loss tangent. The resonant frequencies and Q factors are measured by an Agilent 5242A network analyzer connected to the resonator. Dielectric loss tangent and dielectric constant measurements are carried out at room temperature (25° C.), but this disclosure does not limit dielectric loss tangent and dielectric measurements to any particular temperature.

In one instrument, a Keysight 85072 10-GHz Split Cylinder Resonator (see https://literature.cdn.keysight.com/litweb/pdf/5989-6182EN.pdf?id=1130540), the cavity is a hollow cylinder. It is comprised of two halves, allowing a flat dielectric sample with parallel sides to be placed into a gap between the two sections. After the sample is inserted, one of the halves is moved with a micrometer drive until both halves of the cylinder snugly contact the sample. The cavity is electrically excited by coupling a swept microwave signal from the network analyzer into it using small antennas inside the cavity. The dielectric constant and dielectric loss tangent are determined by comparing the resonant frequency and Q of the sample-loaded cavity to that of the empty cavity. For accurate results, the sample size must be greater than 56×56 mm², the thickness should be between 0.05 mm and 5 mm, and the sample surfaces should be flat and parallel to each other.

Alternatively, dielectric performance of the PCB laminates was assessed using aSplit Post Dielectric Resonator (QWED Company, Poland). (See https://qwed.com.pl). It uses a similar measurement principle to that used in the Keysight instrument, but it employs a different resonator, which operates at 15 GHz. It is particularly suitable for small, thin samples (down to 14×14 mm² in size and less than 0.6 mm thick). In this case, the cavity is simply the gap between two round flat electrodes (i.e., “posts”). The gap is fixed (at 0.6 mm in the case of a 15 GHz resonance frequency) and so is only partially filled by the sample; thus so no mechanical motion is required.

### Example 15: Dielectric Loss Properties for a Nine-Layer PCB Laminate Material (Using Alumina Layers)

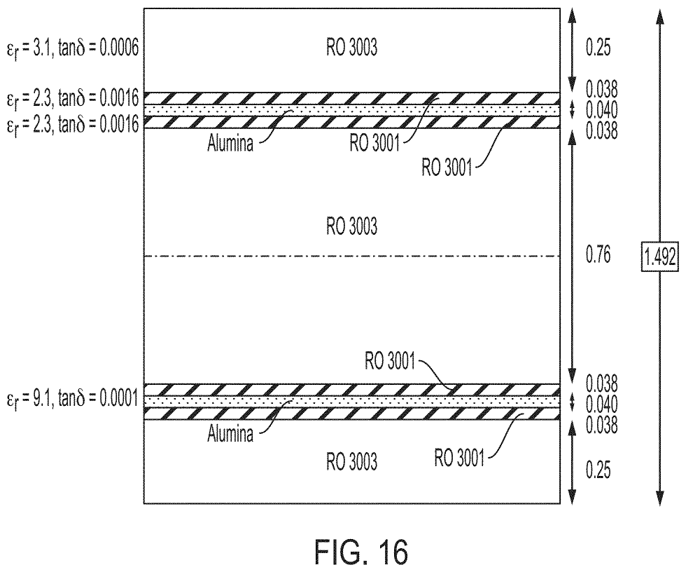

FIG. 16 shows a schematic illustration of a cross-section for a nine-layer laminated PCB laminate material with RO3003 (a commercially-available ceramic-filled PTFE composite, Rogers Corporation) for the polymer layers, alumina for the inorganic layers, and RO3001 (Rogers Corporation) as a bonding film between RO3003 and alumina. The dielectric properties for this nine-layer laminate were calculated according to Equations 1-5. The dielectric properties of the layers are shown on the left, and dimensions (mm) are shown on the right. The calculated longitudinal permittivity and transverse permittivity of the laminate were 3.1 and 3.0, respectively. The calculated longitudinal and transverse loss tangents were 0.0006 and 0.0007, respectively.

To test the calculation methods described in Example 9, the nine-layer laminate schematically illustrated in FIG. 16 was fabricated as described herein. For this laminate, RO3003 was used as a polymer layer to test the calculation methods on commercially available materials. As described below, the actual permittivity and loss tangent, measured in a 10 GHz split cylinder resonator, were 3.0 and 0.0008, respectively, for this nine-layer laminate.

Nine-Layer Laminate Fabrication Procedure

One piece of RO3003 (0.76 mm thick), two additional pieces of RO3003 (0.25 mm thick), and four pieces of RO3001 bonding film (0.038 mm thick) were obtained and cut to 100 mm×100 mm size. Two pieces of alumina (0.070 mm thick) were prepared according to Example 3 and were cut to the same size prior to further processing.

RO3003 is typically sold with copper cladding laminated to both sides. Prior to lamination, the copper films were etched away by immersing the RO3003 pieces in a ferric chloride solution at room temperature for 3.5 hours. The bare RO3003 pieces were then rinsed, first in deionized water, then in isopropanol.

Prior to laminate assembly, the alumina pieces and copper-free RO3003 pieces (but not the RO3001 bonding film) were pre-baked at 140° C. for 75 minutes to drive off residual water. The RO3003, alumina, and RO3001 pieces were then assembled according to the order shown in FIG. 16 and enclosed in a Teflon envelope, which was inserted into a 6-in.×6-in. silicone bag press (Vacuum Laminating Technology, Inc.; SRM50 bag material). The bag press was evacuated to a pressure of about 0.13 atm (using a VP5 Vacuum Pump, Vacuum Laminating Technology, Inc.) and was placed in a vacuum oven (Quincy Lab., Inc., Model 10 Lab Oven). The oven temperature was ramped from room temperature to 205° C. over 0.3 hours, after which the temperature was maintained between 200° C. and 205° C. for approximately 0.7 hours. Following this process, the bag was removed from the vacuum oven and allowed to cool to room temperature before the laminate materials were removed for characterization.

### Example 16: Dielectric Loss Properties of a Nine-Layer PCB Laminate Material (Using Silica Layers)

An analogous nine-layer laminate was fabricated, substituting silica (prepared according to Example 1) for alumina in the inorganic layers. Its flexural rigidity and longitudinal stiffness are increased, and its CTE is decreased, relative to RO3003 alone. At the same time, the loss tangent of this nine-layer composite was 0.0008, slightly worse than that measured for RO3003 (0.0006), but much better than that measured for RO3001 (0.0016) These results indicate that the silica sheets greatly improve the mechanical properties of RO3003/RO3001, without sacrificing their excellent dielectric properties.

### Example 17: Dielectric Loss Properties of Three-Layer PCB Laminate Materials

A split post resonator was used to measure the dielectric properties of the laminates of Topas® with silica or alumina (e.g., those shown in FIGS. 2-4). For these PCB laminates, measurement procedure was as follows:

Overall sample thickness was first measured using a micrometer. The resonant frequency and Q-factor of the empty cavity of the split post dielectric resonator was measured using the Agilent 5242A network analyzer connected to the resonator. For example, for a particular TST sample, the values were 15.305 GHz and 9588.9 respectively. The sample was then inserted into the cavity, and the resonant frequency and Q factor were re-measured as 15.245 GHz and 9473.9. The relative permittivity (2.77) and loss tangent (0.00014) of the sample were calculated from these measured values using software provided by QWED, according to the principles outlined in J. Krupka et al., “Uncertainty of complex permittivity measurements by split-post dielectric resonator technique,” 21 J. EUR. CERAMIC SOC'Y 2673-76 (2001).

### Example 18: Dielectric Loss Tangents for Three- and Seven-Layer PCB Laminates

Referring to FIG. 8, Topas® powder-PTFE composites were prepared by mixing Topas® 6017S powder (Topas® Advanced Polymers) with PTFE powder (MP 1400, Chemours) in a Brabender mixer at 260° C. and 50-80 rpm. The resulting composite polymer mixture was extruded (e.g., according to Example 8) to form polymer composite films.

Fluoropolymer layers (FEP and PFA, Chemours) with thicknesses of 75-125 μm were purchased and used as received or cleaned with water and/or another solvent (e.g., isopropanol, methanol, ethanol, etc.) before incorporation into PCB laminates. Silica fabric layers were prepared using a silica weave (Astroquartz®, JPS Composite Materials) with a low loss tangent (˜0.0003 at 10 GHz or higher frequency). These materials were purchased and used as received or cleaned with water and/or another solvent (e.g., isopropanol, methanol, ethanol, etc.) and then dried before using.

To prepare three-layer PCB laminates, the polymer composite films and fluoropolymer sheets were assembled in the order schematically illustrated in FIG. 6 (Topas®-PTFE/FEP/Topas®-PTFE or Topas®-PTFE/PFA/Topas®-PTFE).

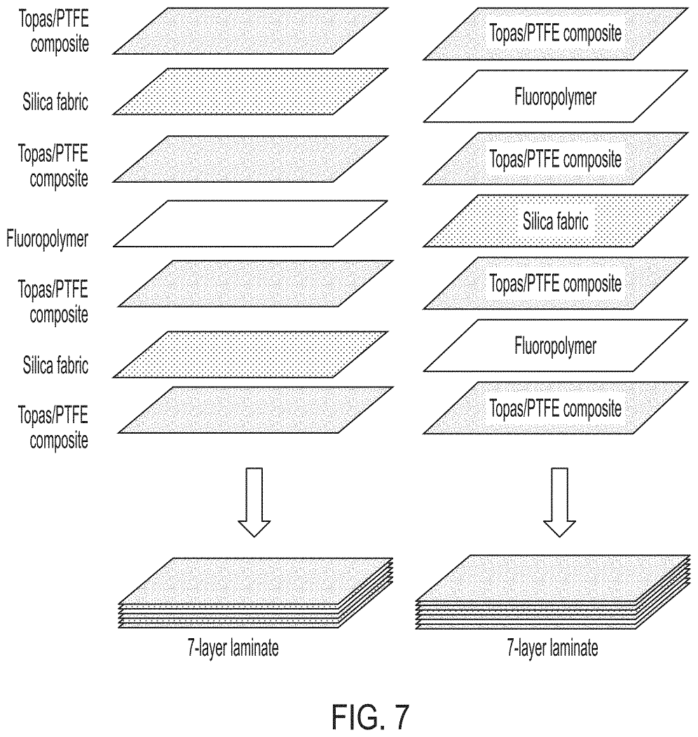

To prepare seven-layer laminates, the polymer composite films, fluoropolymer sheets, and silica fabric layers were assembled in the order schematically illustrated in FIG. 7. The samples were then placed between two stainless steel sheets and laminated using a Carver Lab Press at a temperature of 260° C., at approximately 1000 Pa, for about 1 minute, then removed from the Lab Press and cooled to a temperature of about 50° C., after removing the two stainless steel sheets.

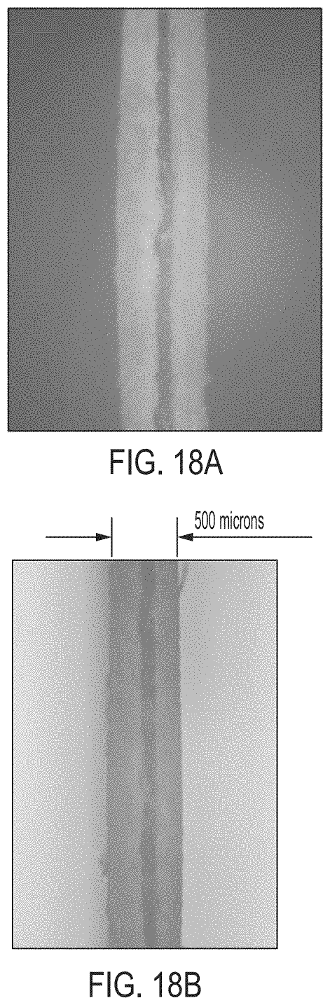

The resulting three-layer PCB laminate structures are shown in the cross-sectional optical images in FIGS. 18A-B (three-layer). The images show that the three-layer laminates have a total thickness of approximately 500 μm. In both structures, the fluoropolymer layer (FEP (FIG. 18A) or PFA (FIG. 18B)) is sandwiched between two polymer composite layers.

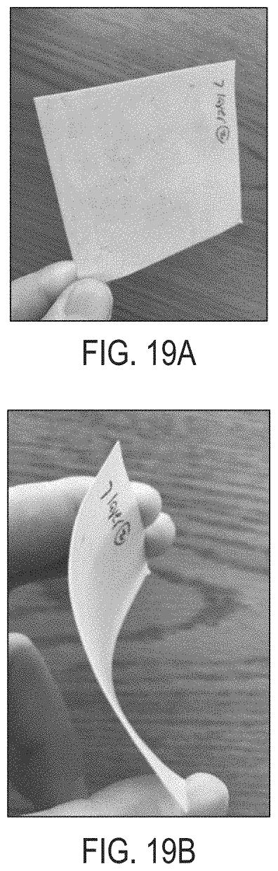

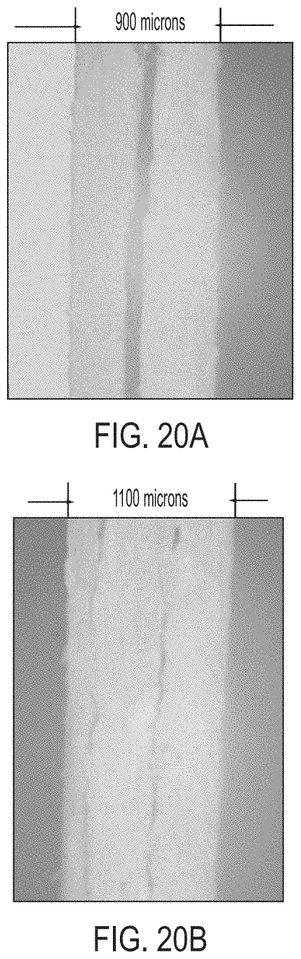

Referring now to FIGS. 20A-B, cross-sectional optical images show structures obtained for seven-layer PCB laminates. The silica fabric layers are buried in the polymer composite layers, so they are not visible. FIG. 20A shows that the seven-layer laminate including a single silica fabric layer and two fluoropolymer layers has a total thickness of approximately 1100 μm. FIG. 20B shows that the seven-layer laminate including two silica fabric layers and one fluoropolymer layer has a total thickness of about 900 μm. Referring to FIGS. 19A-B, the resulting seven-layer laminates are rigid enough to hold their shape without additional support (FIG. 19A) but are flexible enough to bend without damage (FIG. 19B).

Dielectric Loss Tangent Measurements

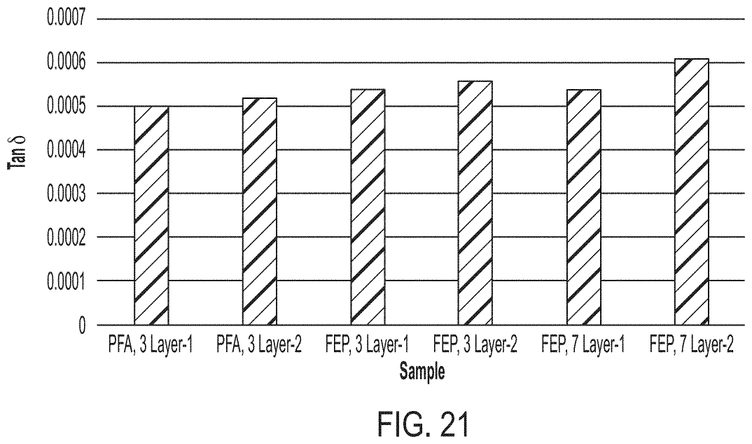

FIG. 21 shows the dielectric loss tangents measured for the three- and seven-layer laminates measured using the split cylinder resonator method described in Example 14. The laminates all show dielectric loss tangents of 0.0005 to 0.0006 at approximately 10 GHz.

Table 8 shows permittivity, loss tangent, measurement frequency, and total thickness for the three- and seven-layer PCB laminates. The fluoropolymer layers used for the different stacked laminates are indicated as “PFA” or “FEP.” The inorganic layers used for the seven-layer laminates were silica fabric layers (Astroquartz®, JPS Composite Materials).

TABLE 8
Dielectric properties and thickness for
three- and seven-layer PCB laminates.

| | | Loss | Frequency | Thickness |
|---|---|---|---|---|
| Sample Description | Permittivity | Tangent | (GHz) | (mm) |
| 3-Layer, PFA #1 | 2.04 | 0.00050 | 9.92 | 0.48 |
| 3-Layer, PFA #2 | 2.14 | 0.00052 | 9.83 | 0.76 |
| 3-Layer, FEP #1 | 2.13 | 0.00054 | 9.87 | 0.56 |
| 3-Layer, FEP #2 | 2.24 | 0.00056 | 9.88 | 0.53 |
| 7-Layer, FEP #1 | 2.33 | 0.00054 | 9.77 | 0.85 |
| 7-Layer, FEP #2 | 1.88 | 0.00061 | 9.72 | 1.19 |

As shown in Table 8, all the laminates tested showed dielectric loss tangents of about 0.0006 or less at approximately 10 GHz, making them suitable PCB materials for high-frequency PCB applications.

### Example 19: Calculating Mechanical and Thermal Properties of Organic/Inorganic Laminates

Flexural Rigidity

FIG. 15 shows a schematic illustration of a three-layer (two-material) PCB laminate material according to the present disclosure. If the PCB laminate material in FIG. 15 is flexed such that the front and back faces are no longer parallel and the side faces are curved, then the curvature (1/p) and the applied bending moment (M) are related by Equation 6.

$$\frac{1}{ρ} = \frac{M}{F} \qquad ( Equation 6 )$$

where F is the flexural rigidity of the PCB. The flexural rigidity of a PCB laminate material (or a PCB consisting of the same) is equal to the sum of the products of the “moment of inertia” (I) and Young's modulus (E) of each layer.

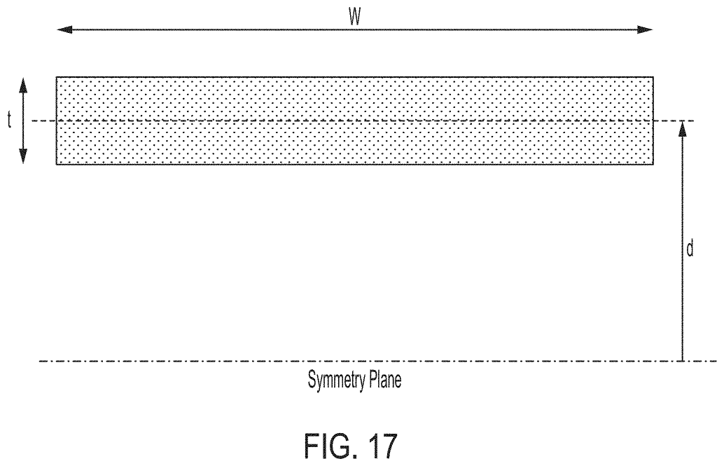

FIG. 17 schematically illustrates a single layer from a PCB laminate material and illustrates how I is calculated for a single layer from its cross-sectional dimensions. In the cross-sectional view, the width and thickness of a particular layer are w and t, respectively, and the center of the layer is offset from the symmetry plane of the laminate by a distance d. The moment of inertia (I) of this layer is calculated according to Equation 7.

$$I = \frac{{wt}^{3}}{12} {d}^{2} wt \qquad ( Equation 7 )$$

For the three-layer laminate shown in FIG. 15, assume that the middle layer is 1 mm thick and consists only of Rogers 3003 (RO3003; E=2 GPa). The top and bottom layers are silica (E=72 GPa), with each layer 80 μm thick and with a Young's modulus of 72 GPa. The width of the laminate (w) is 100 mm. Table 9 shows how the total flexural rigidity of this laminate is determined.

TABLE 9
Flexural Rigidity Calculation for Three-Layer Laminate

| | | t | d | E | I | EI |
|---|---|---|---|---|---|---|
| Layer | Material | (μm) | (μm) | (GPa) | (m⁴) | (Nm²) |
| Top | Silica | 80 | 540 | 72 | 2.35 × 10⁻¹² | 0.169 |
| Middle | RO3003 | 1000 | 0 | 2 | 8.33 × 10⁻¹² | 0.017 |
| Bottom | Silica | 80 | 540 | 72 | 2.35 × 10⁻¹² | 0.169 |

| | |
|---|---|
| Total Flexural Rigidity | 0.355 |

Thus, Table 9 shows that although they are very thin, the silica layers contribute much more to flexural rigidity than does the much thicker layer of RO3003. This is because (i) the Young's modulus of silica is much greater than that of RO3003, and (ii) the silica layers are widely offset from the symmetry plane. After lamination with silica layers, the flexural rigidity of the RO3003 is increased by a factor of over 20.

The longitudinal stiffness (in terms of the “effective Young's modulus”) of the laminate composed of two materials, as shown in FIG. 15, is calculated according to Equation 8.

$${E}_{eff} = \frac{{t}_{1} {E}_{1} + {t}_{2} {E}_{2}}{{t}_{1} + {t}_{2}} \qquad ( Equation 8 )$$

where E₁ and E₂ are the Young's moduli of Materials 1 and 2, respectively. Because the structure shown in FIG. 15 is symmetrical, the PCB will not tend to curl as it is stressed.

Longitudinal Coefficient of Thermal Expansion

Considering a case in which Material 1 is silica (E=72 GPa) and is 160 μm thick, and Material 2 is RO3003 (E=2 GPa) and is 1 mm thick, the effective Young's modulus would then be 11.7 GPa. Thus, in this example, laminating the RO3003 with silica has increased the longitudinal stiffness by a factor of almost 6.

For a two-material composite, the effective coefficient of thermal expansion (“effective CTE”) is described by Equation 9, where α₁ is the CTE of silica (0.55 ppm/° C.), α₂ is the CTE of RO3003 is 17 ppm/° C.

$${α}_{eff} = \frac{{t}_{1} {E}_{1} {α}_{1} + {t}_{2} {E}_{2} {α}_{2}}{{t}_{1} {E}_{1} + {t}_{2} {E}_{2}} \qquad ( Equation 9 )$$

Accordingly, for the same structure shown in FIG. 15, where Material 1 is silica, and Material 2 is RO3003, the “effective CTE” is 2.98 ppm/° C. Thus, the effect of the silica layers is to decrease the CTE of the RO3003 by a factor of 5.7.

For a two-material composite, the “effective transverse thermal conductivity” (κ_{eff}) is determined according to Equation 10, where κ₁ and κ₂ are the thermal conductivities of Material 1 and Material 2, respectively. If Material 1 is silica (κ₁=1.38 W/m·K), and Material 2 is RO3003 (κ₂=0.50 W/m·K), the effective thermal conductivity of the laminate would be 0.55 W/m·K.

$$\frac{1}{{κ}_{eff}} = \frac{{t}_{1} / {κ}_{1} + {t}_{2} / {κ}_{2}}{{t}_{1} + {t}_{2}} \qquad ( Equation 10 )$$

### Example 20: Comparison Between Alumina and Silica Layers—Calculated Properties

The choice of laminating material is not restricted to silica (or indeed to ceramics). Another ceramic material that can be used in one or more inorganic layers according to the present disclosure is alumina (e.g., FIG. 4), which has significantly different electrical and mechanical properties from those of silica. Table 10 shows representative values for relevant material properties. The properties of RO3003 are also shown.

TABLE 10
Comparison of Material Properties
for Silica, Alumina, and RO3003

| Material Property | Units | Silica | Alumina | RO3003 |
|---|---|---|---|---|
| Permittivity | | 3.9 | 9.8 | 3.1 |
| Loss Tangent | | 0.0001 | 0.0002 | 0.0006 |
| Young's Modulus | GPa | 72 | 375 | 2 |
| CTE | ppm/K | 0.55 | 8.4 | 17 |
| Thermal Conductivity | W/K · m | 1.38 | 35 | 0.50 |

Table 11 compares the calculated properties of three-layer laminates consisting of a 1-mm thick layer of RO3003 sandwiched between two layers of silica or alumina, each 80 μm thick. Again, the width of the laminate PCB is 100 mm.

TABLE 11
Calculated Dielectric, Mechanical, and Thermal Properties
of SiO₂/RO3003 and Al₂O₃/RO3003 Three-Layer Laminates

| | | | |
|---|---|---|---|
| | | Silica/ | Alumina/ |
| Property | Units | RO3003 | RO3003 |

Dielectric Properties

| | | |
|---|---|---|
| Longitudinal Permittivity | 3.2 | 4.0 |
| Longitudinal Loss Tangent | 0.00052 | 0.00047 |
| Transverse Permittivity | 3.2 | 3.4 |
| Transverse Loss Tangent | 0.00054 | 0.00058 |

Mechanical/Thermal Properties

| | | | |
|---|---|---|---|
| Flexural Rigidity | N · m² | 0.35 | 1.77 |
| Longitudinal Stiffness | GPa | 11.7 | 53.5 |
| CTE | ppm/K | 3.0 | 8.7 |
| Transverse Thermal Conductivity | W/K · m | 0.55 | 0.58 |

As illustrated in Table 11, the greater Young's modulus of alumina (see Table 10) leads to a stiffer laminate. Its greater CTE increases the effective CTE of the composite by a factor of almost 3, relative to silica/RO3003 composites. Although the thermal conductivity of alumina is greater than that of silica by a factor of over 25, the effect on the transverse thermal conductivity of the laminate is negligible because the thermal resistance of the RO3003 is heavily dominant.

### Example 21: Mechanical Characterization of Three-Layer PCB Laminate Structures

Samples of PCB laminate materials have been characterized mechanically, principally to measure flexural modulus and flexural strength and to assess qualitatively their drilling properties. For example, three-layer laminates made from Topas® and silica have been characterized in this manner.

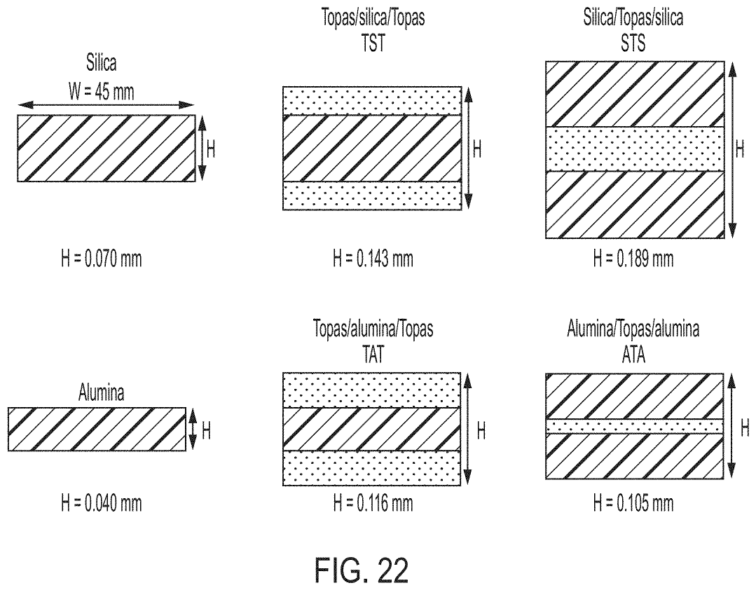

FIG. 22 shows the PCB laminate structures that were prepared and tested, together with their cross-sectional dimensions. In all cases, the samples were 45 mm wide. For the silica laminates, the thickness of silica was 0.070 mm; for the alumina laminates, the thickness of alumina was 0.040 mm. (The dimensions are averages of five or six measurements made on different samples, and the superscripted numbers are the standard deviations.) For the silica laminates, the lengths of the samples were about 40 mm; for the alumina laminates, the sample lengths were 24 mm or 32 mm. Topas®/silica/Topas® laminates are labeled “TST”; silica/Topas®/silica laminates are labeled “STS”; Topas®/alumina/Topas® laminates are labeled “TAT”; and alumina/Topas®/alumina laminates are labeled “ATA”.

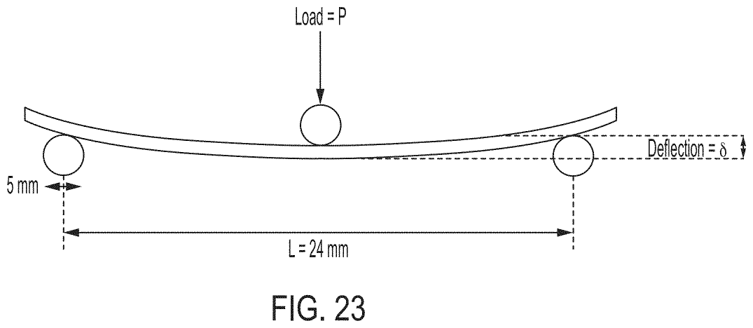

FIG. 23 illustrates the principle of the three point bend test setup for measuring flexural modulus and flexural strength. The test stand, force gauge and bend fixtures were all obtained from Mark-10 (see http://www.mark10.com). The rollers on the top and bottom test fixtures were 5 mm in diameter, and the distance between the bottom rollers (L) was set to 24 mm. The deflection at the center of the sample (δ) was measured using a Fowler dial indicator. (See http://www.fowlerprecision.com/Products/Dial-Indicators). The load (P) was applied via the Mark-10 force gauge.

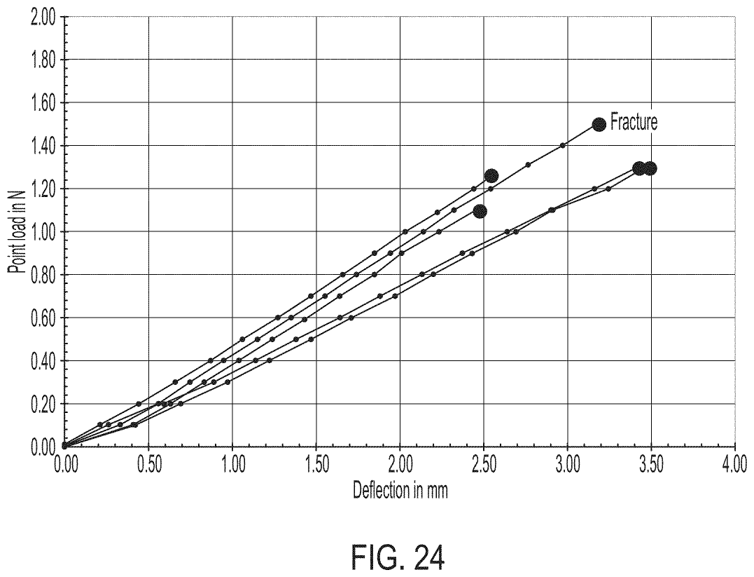

Load-deflection plots for five Topas®/silica/Topas® (TST) samples are shown in FIG. 24. Fracture is indicated by the large dots at the end of each plot. The plots are substantially linear, and the gradients indicate the flexural moduli. The load at fracture indicates the flexural modulus for each sample.

The flexural modulus of a sample is calculated from Equation 11:

$${E}_{bend} = \frac{{L}^{3}}{4 W {H}^{3}} ( \frac{P}{δ} ) , \qquad ( Equation 11 )$$

where L is defined in FIG. 23, W and H are defined in FIG. 22, and (P/δ) is the gradient of the load-deflection curve (FIG. 24).

The flexural strength is calculated from Equation 12:

$${σ}_{frac} = \frac{3 L}{2 W {H}^{2}} {P}_{frac} , \qquad ( Equation 12 )$$

where P_{frac} is the load at fracture.

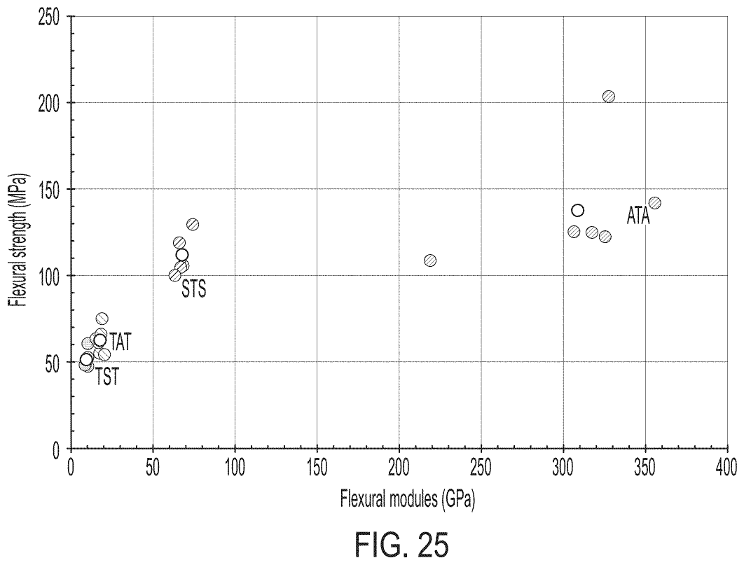

FIG. 25 shows the measured flexural moduli and flexural strengths for TST (markers are black dots on white background), STS (white dots on black background), TAT (downward sloping diagonal stripes) and ATA (upward sloping diagonal stripes). In all cases, the average values are shown as white filled markers with black borders. Table 12 summarizes the flexural moduli and flexural strengths of the laminate samples.

TABLE 12
Flexural Moduli and Flexible Strengths for TST,
STS, TAT, and ATA PCB Laminate Materials.

| Laminate | Flexural modulus (GPa) | Flexural strength (MPa) |
|---|---|---|
| TST | 9.2 | 51 |
| STS | 68 | 112 |
| TAT | 17 | 63 |
| ATA | 308 | 137 |

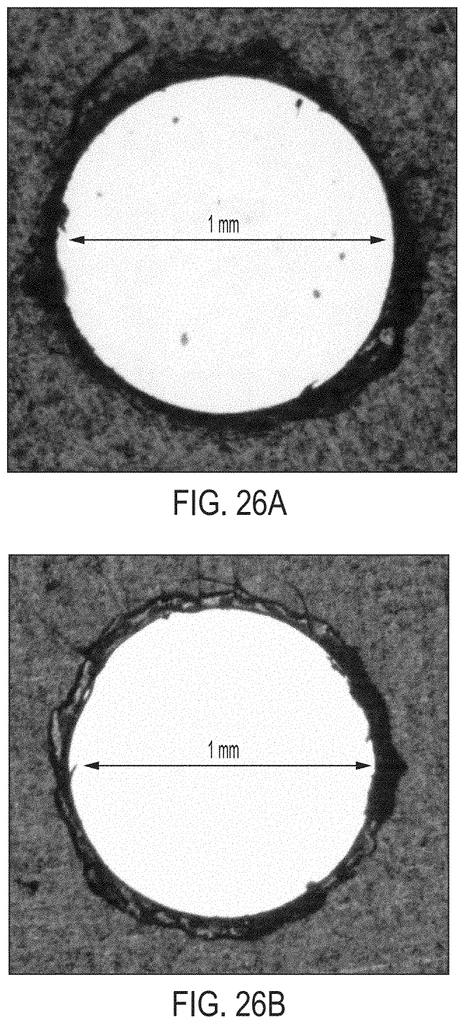

The drilling properties of the laminates were tested by drilling 1.0-mm holes through the laminate structures. The drill speed was 3000 rpm, and the laminates were supported on a solid wooden block. The drills were type Drl-0394 obtained from North Bay Technical. (See https://pcbprototyping.com/services/.) FIGS. 26A-B show optical micrographs of holes drilled through Topas®/silica/Topas® (TST) (FIG. 26A) and Topas®/alumina/Topas® (TAT) (FIG. 26B) PCB laminates. The Figures show that the laminates do not crack and exhibit minimal burring, reflecting their enhanced flexural strength. Thus, PCB laminate materials according to the present disclosure, in addition to possessing the dielectric properties required for high-frequency (10 GHz or higher) applications, possess sufficient mechanical strength and toughness to withstand processing conditions required for PCB production (e.g., for via drilling).

What is claimed is:

1. A printed circuit board (PCB) laminate material, comprising:
(a) a first layer selected from a polymer layer, an inorganic layer, and an infiltrated inorganic layer; and
(b) a second layer selected from a polymer layer, an inorganic layer, and an infiltrated inorganic layer;
wherein the first layer is laminated to the second layer and the loss tangent of the PCB laminate material is no greater than 0.005 at 10 GHz or higher frequency.

2. The PCB laminate material of claim 1, wherein the PCB laminate material has a dielectric constant of less than or equal to 10.

3. The PCB laminate material of claim 1, wherein the PCB laminate material has a flexural modulus of about 1 GPa to about 400 GPa or a flexural strength of about 20 MPa to about 400 MPa.

4. The PCB laminate material of claim 1, wherein the first layer and/or the second layer is an inorganic layer having a thickness between 20 μm and 700 μm.

5. The PCB laminate material of claim 4, wherein the inorganic layer comprises a glass having at least one of (i) a thickness less than or equal to 200 μm and (ii) a dielectric loss tangent of less than or equal to about 0.006 at 10 GHz (or higher frequency).

6. The PCB laminate material of claim 1, wherein the first layer and/or the second layer comprises a polymer layer.

7. The PCB laminate material according to claim 6, wherein the polymer layer comprises at least one polymer selected from cyclic olefin copolymers, polystyrene polymers, fluoropolymers, polyetheretherketone polymers, polyetherimide polymers, liquid crystal polymers, polypropylene polymers, cyclic olefins, linear olefins, bi-cyclic olefin norbornene and ethylene, or combinations thereof.

8. The PCB laminate material of claim 6, wherein the polymer layer comprises a polymer composite material, the polymer composite material comprising a cyclic olefin copolymer and a fluoropolymer, wherein the cyclic olefin copolymer and the fluoropolymer are present in a ratio of between 1:99 and 99:1.

9. The PCB laminate material of claim 6, wherein the polymer layer comprises polytetrafluoroetheylene (PTFE, e.g., Teflon®), fluorinated ethylene propylene (FEP), poly(vinylidene) fluoride (PVDF), ethylene chlorotrifluoroethylene (ECTFE), perfluoroalkoxy (PFA), or combinations thereof.

10. A printed circuit board (PCB), comprising:
(a) a PCB laminate material having a first side and a second side, the PCB laminate material comprising:
(i) a first layer selected from a polymer layer, an inorganic layer, and an infiltrated inorganic layer; and
(ii) a second layer selected from a polymer layer, an inorganic layer, and an infiltrated organic layer, wherein the first layer is laminated to the second layer; and
(b) at least one conductive cladding layer laminated onto the first side of the PCB laminate material;
wherein the PCB laminate material (a) has a dielectric loss tangent of no greater than 0.005 at 10 GHz (or higher frequency).

11. The printed circuit board (PCB) of claim 10, wherein the PCB laminate material (a) has a dielectric constant of less than or equal to 10.

12. The printed circuit board (PCB) of claim 10, wherein the PCB laminate material (a) has a flexural modulus of about 1 GPa to about 400 GPa or a flexural strength of about 20 MPa to about 400 MPa.

13. The printed circuit board of claim 10, further comprising a second conductive layer laminated onto the second side of the PCB laminate material.

14. The printed circuit board of claim 10, wherein the first layer and/or the second layer is an inorganic layer having a thickness of 20 μm to 700 μm.

15. The printed circuit board of claim 14, wherein the inorganic layer comprises a glass layer having at least one of (i) a thickness less than or equal to 200 μm and (ii) a dielectric loss tangent of less than or equal to about 0.006 at 10 GHz (or higher frequency).

16. The printed circuit board of claim 10, wherein the first layer and/or the second layer comprises a polymer layer.

17. The printed circuit board of claim 16, wherein the polymer layer comprises at least one polymer selected from cyclic olefin copolymers, polystyrene polymers, fluoropolymers, polyetheretherketone polymers, polyetherimide polymers, liquid crystal polymers, polypropylene polymers, cyclic olefins, linear olefins, bi-cyclic olefin norbornene and ethylene, or combinations thereof.

18. The printed circuit board of claim 16, wherein the polymer layer comprises a polymer composite material, comprising a cyclic olefin copolymer and a fluoropolymer, wherein the cyclic olefin copolymer and the fluoropolymer are present in a ratio between 1:99 and 99:1.

19. The printed circuit board of claim 16, wherein the polymer layer comprises polytetrafluoroetheylene (PTFE, e.g., Teflon®), fluorinated ethylene propylene (FEP), poly(vinylidene) fluoride (PVDF), ethylene chlorotrifluoroethylene (ECTFE), perfluoroalkoxy (PFA), or combinations thereof.

20. A method of making a printed circuit board, comprising:
(a) preparing a PCB laminate material, comprising:
(i) contacting a first layer selected from a polymer layer, an inorganic layer, and an infiltrated inorganic layer with a second layer selected from a polymer layer, an inorganic layer, and an infiltrated inorganic layer; and
(ii) laminating the first layer to the second layer to produce a PCB laminate material having a dielectric loss tangent of no greater than 0.005 at 10 GHz (or higher frequency); and
(b) laminating the PCB laminate material to at least one conductive cladding layer,
wherein step (ii) comprises heating the first layer and second layer.
